(19) United States
(12) Patent Application Publication
(10) Pub. No.: US 2007/0003783 A1
(43) Pub. Date: Jan. 4, 2007

(54) Quinoline copolymer and organic electroluminescent device employing same

(75) Inventors: Yoshii Morishita, Ibaraki (JP); Satoyuki Nomura, Ibaraki (JP); Yoshihiro Tsuda, Ibaraki (JP); Seiji Tai, Ibaraki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignees: Hitachi Chemical Co Ltd, Tokyo (JP); Maxdem Incorporated, San Dimas, CA (US)

(21) Appl. No.: 10/553,640

(22) PCT Filed: Apr. 16, 2004
(86) PCT No.: PCT/JP04/05485

§ 371 Date: Aug. 15, 2006

(30) Foreign Application Priority Data
Apr. 18, 2003 (JP) 2003-114840

(51) Int. Cl. B32B 19/00

(52) U.S. Cl. 428/690

(57) ABSTRACT

The present invention relates to a quinoline copolymer containing an optionally substituted quinoline monomer unit and an optionally substituted benzotriazole monomer unit. It is an object of the present invention to provide a light-emitting polymer material having excellent stability.

### TECHNICAL FIELD

The present invention relates to a quinoline copolymer and an organic electroluminescent (EL) device employing same.

### BACKGROUND ART

Electroluminescent devices have been attracting attention as, for example, large-area solid state light sources to replace incandescent lamps and gas-filled lamps. They have also been attracting attention as self-luminous displays, and are the most promising alternative to liquid crystal displays in the flat panel display (FPD) field. In particular, an organic electroluminescent (EL) device, in which the device material is formed from an organic material, is being commercialized as a low power consumption full-color FPD. Above all, polymer-based organic EL devices will be indispensable for future large-screen organic EL displays since the organic material of the polymer-based organic EL devices is formed from a polymer material for which film formation by printing, ink-jet, etc. is simple compared with low molecular weight-based organic EL devices, which require film formation in a vacuum system.

Conventionally, polymer-based organic EL devices employ either a conjugated polymer such as poly(p-phenylene-vinylene) (see e.g. International Publication WO90/13148) or a non-conjugated polymer (see e.g. I. Sokolik, et al., J. Appl. Phys. 1993. 74, 3584) as the polymer material. However, their luminescence lifetime when used in a device is short, which gives rise to problems when constructing a full-color display.

With the object of solving these problems, polymer-based organic EL devices employing various types of polyfluorene-based and poly(p-phenylene)-based conjugated polymers have been proposed in recent years, but they are not satisfactory in terms of stability.

While taking into consideration the above-mentioned conventional problems, it is an object of the present invention to provide a light-emitting polymer material having excellent stability. It is another object of the present invention to provide an organic EL device that has an excellent luminescence lifetime.

### DISCLOSURE OF INVENTION

As a result of an intensive investigation by the present inventors, it has been found that a copolymer containing a quinoline derivative and a benzotriazole derivative is an excellent material as a light-emitting polymer having excellent stability, and the present invention has thus been accomplished.

That is, in accordance with the present invention, there is provided a quinoline copolymer comprising a quinoline monomer unit and a benzotriazole monomer unit. The quinoline monomer unit and the benzotriazole monomer unit may have a substituent.

Furthermore, in accordance with the present invention, there is provided the quinoline copolymer wherein it is a copolymer comprising a quinoline monomer unit represented by Formulae (I): 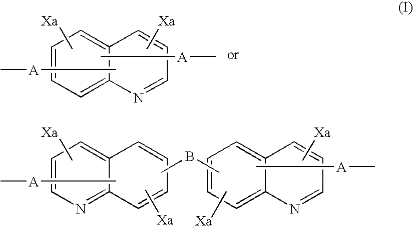
(in the formulae, each X is independently a substituent selected from the group consisting of R¹, —OR², —SR³, —OCOR⁴, —COOR⁵, and —SiR⁶R⁷R⁸ (here, R¹ to R⁸ are independently a C1 to C22 straight-chain, cyclic, or branched alkyl group, or a C2 to C20 aryl or heteroaryl group), the substituents may be identical to or different from each other and are bonded to substitutable positions of the quinoline residue, and each a is independently an integer of 0 to 3; each A is a group selected from the group consisting of a single bond and an arylene group; and B is a divalent linking group selected from the group consisting of a single bond, —O—, —S—, —C(O)—, —S(O)—, —S(O₂)—, —W—, —(—O—W—)ₘ—O—(m is an integer of 1 to 3), and -Q- (W is a divalent group selected from the group consisting of —Ra—, —Ar′—, —Ra—Ar′—, -Ra′—O—Ra′—, —Ra′—C(O)O—Ra′—, —Ra′—NHCO—Ra′—, —Ra—C(O)—Ra—, —Ar′—C(O)—Ar′—, -Het′, —Ar′—S—Ar′—, —Ar′—S(O)—Ar′—, —Ar′—S(O₂)—Ar′—, and —Ar′QAr′—, Ra is an alkylene group, Ar′ is an arylene group, each Ra′ is independently a group selected from the group consisting of an alkylene group, an arylene group, and a mixed alkylene/arylene group, Het′ is a heteroarylene group, and Q is a divalent group containing a quaternary carbon)) and an optionally substituted benzotriazole monomer unit ,and a group linking the monomer units is represented by Formula (II):
-(D) b- (II)
(in the formula, D is a divalent group selected from the group consisting of —O—, —S—, —NR—, —CR₂—, —SiR₂—, —SiR₂—O—SiR₂—, and —SiR₂—O—SiR₂—O—SiR₂— (here, each R is independently a hydrogen atom, a C1 to C22 straight-chain, cyclic, or branched alkyl group, or a C2 to C20 aryl or heteroaryl group), and b is an integer of 0 to 1).

Moreover, in accordance with the present invention, there is provided the quinoline copolymer wherein the optionally substituted benzotriazole monomer unit is represented by Formula (III): 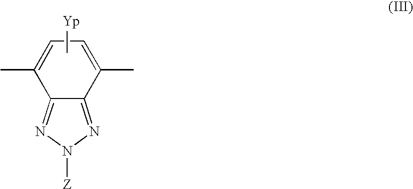
(in the formula, each Y is independently a substituent selected from the group consisting of a halogen atom, —R¹, —OR², —SR³, —OCOR⁴, —COOR⁵, and —SiR⁶R⁷R⁸ (here, R¹ to R⁸ are independently a C1 to C22 straight-chain, cyclic, or branched alkyl group, or a C2 to C20 aryl or heteroaryl group), the substituents may be identical to or different from each other and are bonded to substitutable positions of the benzene ring of the benzotriazole skeleton, and p is an integer of 0 to 2. In the formula, Z is a group selected from the group consisting of optionally substituted alkyl, aryl, and heteroaryl groups).

Furthermore, in accordance with the present invention, there is provided the quinoline copolymer, wherein X in Formulae (I) is —R¹ (here, each R¹ is independently a C1 to C22 straight-chain, cyclic, or branched alkyl group or a C2 to C20 aryl or heteroaryl group), and each a is independently an integer of 0 to 3.

Moreover, in accordance with the present invention, there is provided the quinoline copolymer, wherein Y in Formula (III) is —R¹ (here, each R¹ is independently a C1 to C22 straight-chain, cyclic, or branched alkyl group or a C2 to C20 aryl or heteroaryl group), p is an integer of 0 to 2, and Z is an optionally substituted phenyl group.

Furthermore, in accordance with the present invention, there is provided an electroluminescent device employing the quinoline copolymer, the electroluminescent device preferably comprising a pair of electrodes and one or more organic layers formed between the electrodes, and at least one of the organic layers containing the quinoline copolymer of the present invention.

The disclosures of the present invention relate to subject matter described in Japanese Patent Application No. 2003-114840 filed on Apr. 18, 2003, and the disclosures therein are incorporated herein by reference.

### BEST MODE FOR CARRYING OUT THE INVENTION

The quinoline copolymer of the present invention is a copolymer comprising an optionally substituted quinoline monomer unit and an optionally substituted benzotriazole monomer unit.

The quinoline monomer unit and the benzotriazole monomer unit may each be substituted with a monovalent organic residue at a substitutable position of the monomer unit.

Examples of the organic residue include an aliphatic hydrocarbon residue, an aromatic hydrocarbon residue, an alkoxy group, an aryloxy group, an alkylthio group, an arylthio group, an acyloxy group, an alkoxycarbonyl group, an aryloxycarbonyl group, an alkylsilyl group, an arylsilyl group, an acyl group, an amino group, a nitro group, a cyano group, a halogen group, a hydroxyl group, a mercapto group, a formyloxy group, a carboxyl group, a silyl group, a formyl group, a sulfino group, and a sulfo group.

Examples of the aliphatic hydrocarbon residue include straight-chain, cyclic, or branched alkyl, alkenyl, and alkynyl groups, which preferably have 1 to 22 carbons. Specific examples thereof include methyl, ethyl, propyl, isopropyl, cyclopropyl, butyl, isobutyl, cyclobutyl, pentyl, isopentyl, neopentyl, cyclopentyl, hexyl, cyclohexyl, heptyl, cycloheptyl, octyl, nonyl, decyl, vinyl, propenyl, allyl, propynyl, isopropenyl, butenyl, and pentenyl.

Examples of the aromatic hydrocarbon residue include an aryl group and a heteroaryl group, which preferably have 2 to 20 carbons. Specific examples thereof include phenyl, tolyl, xylyl, mesityl, cumenyl, benzyl, phenethyl, methylbenzyl, diphenylmethyl, styryl, cinnamyl, a biphenyl residue, a terphenyl residue, naphthyl, anthryl, fluorenyl, a furan residue, a thiophene residue, a pyrrole residue, an oxazole residue, a thiazole residue, an imidazole residue, a pyridine residue, a pyrimidine residue, a pyrazine residue, a triazine residue, a quinoline residue, and a quinoxaline residue. In the present invention, the aryl group means an aromatic compound residue, the aromatic compound includes a monocyclic aromatic compound and a polycyclic aromatic compound and, furthermore, the polycyclic aromatic compound includes a compound in which at least two ring structures are bonded and a compound in which at least two ring structures are condensed. In the present invention, heteroaryl means a heterocyclic compound, and the heterocyclic compound includes a heteromonocyclic compound and a condensed heterocyclic compound.

Examples of the alkoxy group include methoxy, ethoxy, propoxy, butoxy, tert-butoxy, octyloxy, and tert-octyloxy, and examples of the aryloxy group include phenoxy, 4-tert-butylphenoxy, 1-naphthyloxy, 2-naphthyloxy, and 9-anthryloxy. Examples of the alkylthio group include methylthio, ethylthio, tert-butylthio, hexylthio, and octylthio, and examples of the arylthio group include phenylthio, 2-methylphenylthio, and 4-tert-butylphenylthio. Examples of the acyloxy group include acetoxy and benzoyloxy. Examples of the alkyloxycarbonyl group include methoxycarbonyl, ethoxycarbonyl, and tert-butoxycarbonyl, and examples of the aryloxycarbonyl group include phenoxycarbonyl and naphthyloxycarbonyl. Examples of the alkylsilyl group include trimethylsilyl and triethylsilyl, and examples of the arylsilyl group include triphenylsilyl. Examples of the acyl group include acetyl, propionyl, benzoyl, and toloyl. Examples of the amino group include amino, N-methylamino, N-ethylamino, N,N-diethylamino, N,N-diisopropylamino, N,N-dibutylamino, N-benzylamino, N,N-dibenzylamino, N-phenylamino, and N,N-diphenylamino. Examples of halogen atoms include fluorine, chlorine, bromine, and iodine.

In the present invention, when the quinoline monomer unit has a substituent, it is preferably an aromatic hydrocarbon residue, preferably an aryl group, and more preferably phenyl. When the benzotriazole monomer unit has a substituent, a substituent that is on the benzene ring of the benzotriazole structure is preferably an aliphatic hydrocarbon residue, and more preferably an alkyl group, and a substituent that is on the triazole ring is preferably an aromatic hydrocarbon residue, more preferably an aryl group, and preferably phenyl.

Furthermore, the substituent that is on the quinoline monomer unit or the benzotriazole monomer unit may further have a substituent, and examples of the substituent include the above-mentioned substituents that may be on the quinoline monomer unit or the benzotriazole monomer unit.

In the present invention, the quinoline monomer unit may further contain in the main chain forming the monomer unit a divalent organic residue other than the quinoline structure. In the present invention, an example of the divalent organic residue is a divalent organic residue corresponding to the above-mentioned monovalent organic residue and formed by removing one hydrogen atom, etc. from the monovalent organic residue. Such an organic residue is preferably an aromatic hydrocarbon residue, more preferably an arylene group, and yet more preferably ortho-phenylene, meta-phenylene, or para-phenylene.

Furthermore, the quinoline monomer unit includes not only a case in which the monomer unit is formed from one quinoline structure as the main chain, but also a case in which one monomer unit is formed by bonding two or more quinoline structures as the main chain. In this case, a group linking the two or more quinoline structures is a single bond or a divalent organic residue, and two or more organic residues may be connected. The organic residue is preferably an aromatic hydrocarbon residue or a divalent group having an oxy group, and is preferably a phenyl residue, a phenanthrene residue, a fluorene residue, a carbazole residue, a biphenyl residue, or a diphenyl ether residue.

The linking group that links monomer units together is not particularly limited, but is preferably a single bond or a divalent organic residue, and the organic residue is preferably an oxy group.

The quinoline copolymer of the present invention may contain at least each of the above-mentioned monomer compounds, and each of the monomer units may be contained randomly in the copolymer as in a so-called random copolymer, or it may be a copolymer in which certain monomer units are localized as in a block copolymer or a graft copolymer. Each of the two types of monomer units forming the above-mentioned copolymer may be a single type of monomer or a combination of two or more types of monomers.

The quinoline monomer unit used in the present invention is preferably represented by Formulae (I). 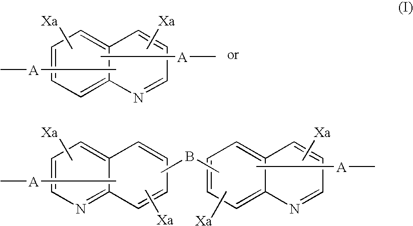
The quinoline monomer unit can be used singly or in a combination of two or more types.

In Formulae (I), each X is independently a monovalent organic residue, and each A and B are independently a single bond or a divalent organic residue.

Among the quinoline monomer units of Formulae (I) of the present invention, one or a plurality of substituents X are preferably represented by —R¹, —OR², —SR³, —OCOR⁴, —COOR⁵, or —SiR⁶R⁷R⁸, and when there are a plurality of substituents X, they may be identical substituents or different substituents from each other. Each a is independently an integer of 0 to 3.

It is preferable for R¹ to R⁸ of the substituent X to be independently a C1 to C22 straight-chain alkyl, cyclic alkyl, or branched alkyl group, or a C2 to C20 aryl or heteroaryl group. Examples of such groups include C1 to C22 straight-chain alkyl, cyclic alkyl, or branched alkyl groups such as methyl, ethyl, propyl, cyclopropyl, butyl, isobutyl, cyclobutyl, pentyl, isopentyl, neopentyl, cyclopentyl, hexyl, cyclohexyl, heptyl, cycloheptyl, octyl, nonyl, and decyl, and C2 to C20 aryl or heteroaryl groups such as phenyl, naphthyl, anthryl, fluorenyl, a biphenyl residue, a terphenyl residue, a furan residue, a thiophene residue, a pyrrole residue, an oxazole residue, a thiazole residue, an imidazole residue, a pyridine residue, a pyrimidine residue, a pyrazine residue, a triazine residue, a quinoline residue, and a quinoxaline residue.

The substituent X may further have a substituent. Examples of the substituent on X include a substituent represented by the above-mentioned —R¹, —OR², —SR³, —OCOR⁴, —COOR⁵, or —SiR⁶R⁷R⁸, and a substituent represented by —NR⁹R¹⁰ (here, R⁹ and R¹⁰ are independently a C1 to C22 straight-chain, cyclic, or branched alkyl group, or a C2 to C20 aryl or heteroaryl group). When there are a plurality of substituents, the plurality of substituents may be identical to or different from each other.

Among the quinoline monomer units of Formulae (I) in the present invention, it is preferable, from the viewpoint of solubility and heat resistance, for each Xa to be independently one in which a is 0, that is, there is no substituent, or one in which X is a direct alkyl or aryl group substituent represented by —R¹. With regard to the number of substituents, including a case in which there is no substituent, that is, a is 0, a is preferably 1 or 2 from the viewpoint of polymerization reactivity. Furthermore, —R¹ is preferably an aryl group, and particularly preferably phenyl.

In the quinoline monomer unit of Formulae (I), it is preferable for each A to be independently a single bond or an arylene group, more preferably an arylene group, and particularly preferably, from the viewpoint of polymerization reactivity, ortho-phenylene, meta-phenylene, or para-phenylene.

Among the quinoline monomer units of Formulae (I), it is preferable for B to be a divalent linking group selected from the group consisting of a single bond, —O—, —S—, —C(O)—, —S(O)—, —S(O₂)—, —W—, —(—O—W—)ₘ—O— (is an integer of 1 to 3), and -Q-. The above-mentioned W is a divalent group selected from the group consisting of —Ra—, —Ar′—, —Ra—Ar′—, —Ra′—O—Ra′—, —Ra′—C(O)O—Ra′—, —Ra′—NHCO—Ra′—, —Ra—C(O)—Ra—, —Ar′—C(O)—Ar′—, -Het′-, —Ar′—S—Ar′—, —Ar′—S(O)—Ar′—, —Ar′—S(O₂)—Ar′—, and —Ar′-Q-Ar′—, Ra is an alkylene group, Ar′ is an arylene group, each Ra′ is independently a group selected from the group consisting of an alkylene group, an arylene group, and an mixed alkylene/arylene group, Het′ is a heteroarylene group, and Q is a divalent group containing a quaternary carbon. B is more preferably a single bond, —O—, —Ar′—, or —Ra′—O—Ra′— and, from the viewpoint of polymerization reactivity, is particularly preferably a phenyl residue, a phenanthrene residue, a fluorene residue, a carbazole residue, a biphenyl residue, or a diphenyl ether residue.

In Formulae (I), the divalent group represented by A or B may have a substituent. Examples of the substituent on A or B include substituents represented by the above-mentioned —R¹, —OR², —SR³, —OCOR⁴, —COOR⁵, —SiR⁶R⁷R⁸, or —NR⁹R¹⁰. When there are a plurality of substituents, the plurality of substituents may be identical to or different from each other.

As specific examples of the quinoline monomer unit of Formulae (I), example compounds are listed below, but they should not be construed as being limited thereto.

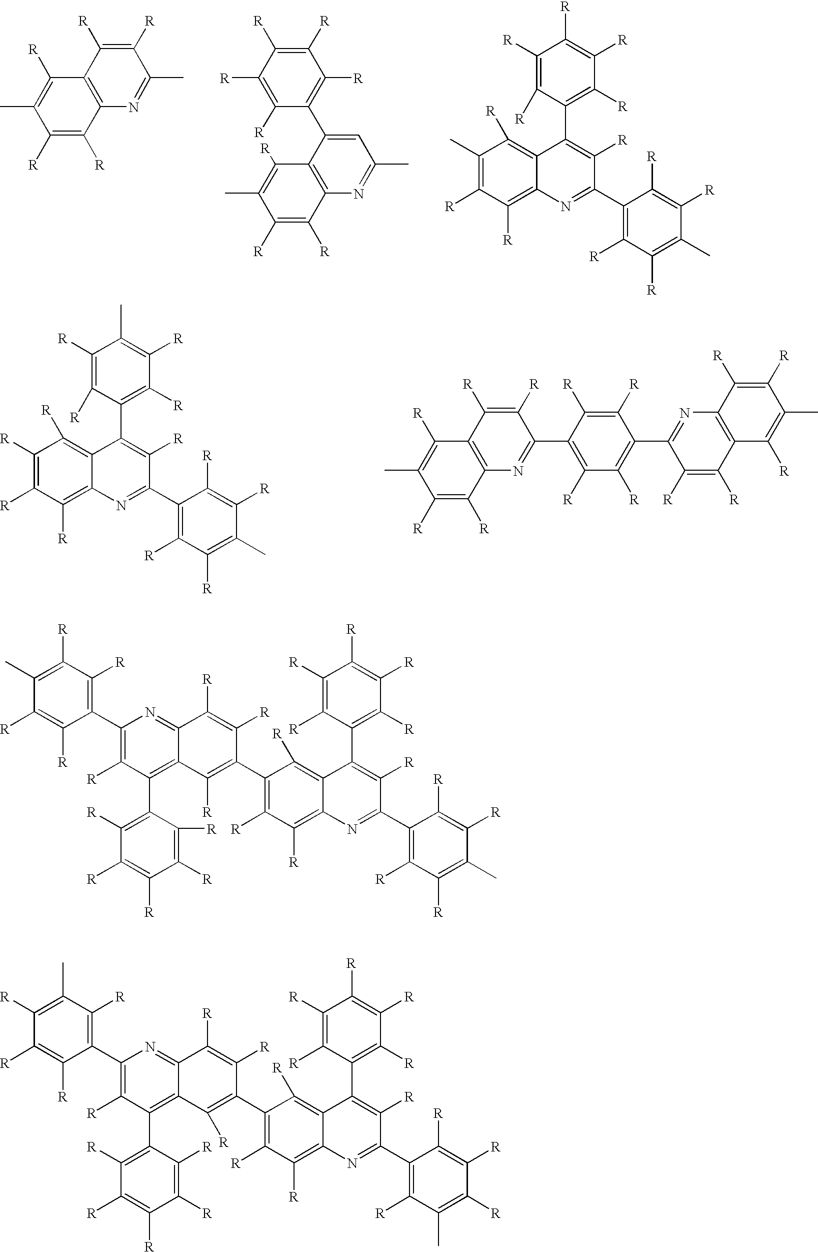

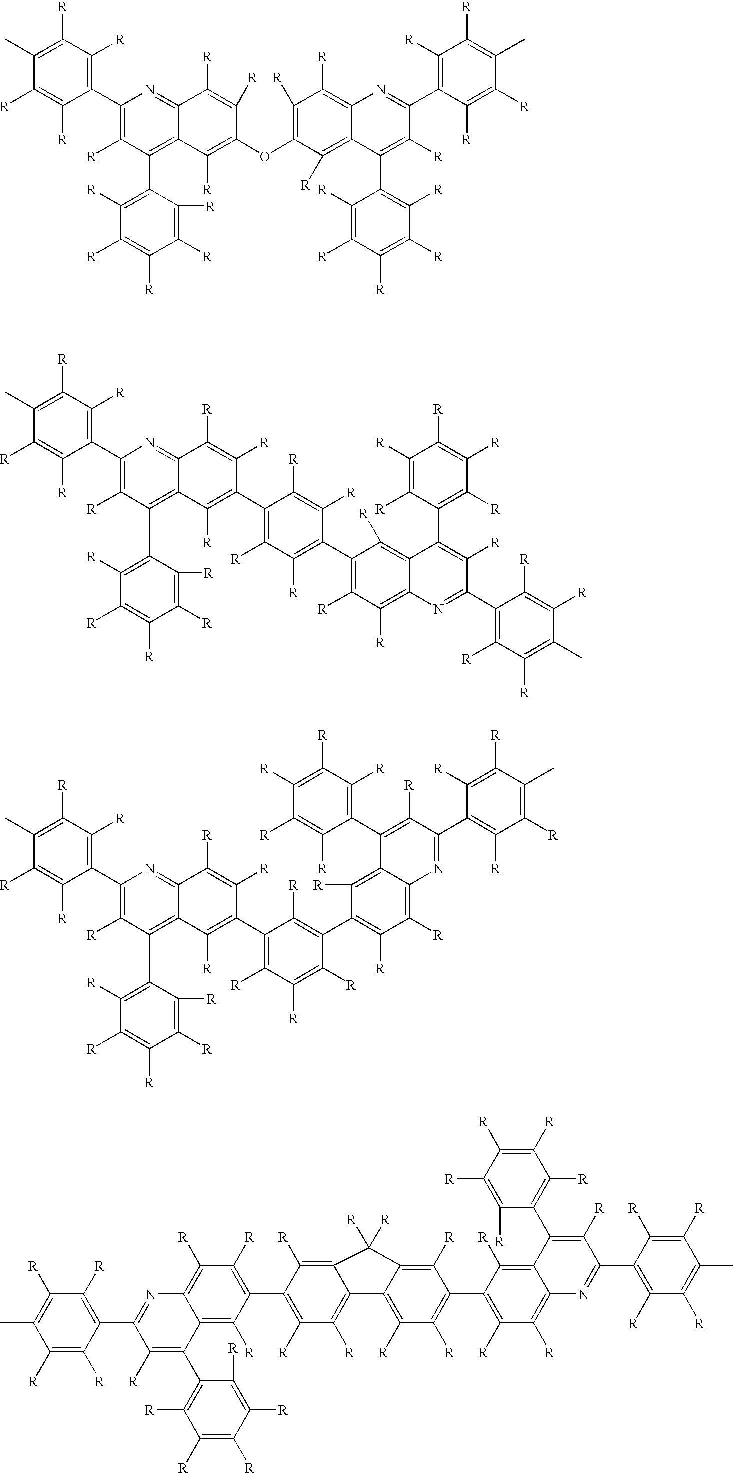

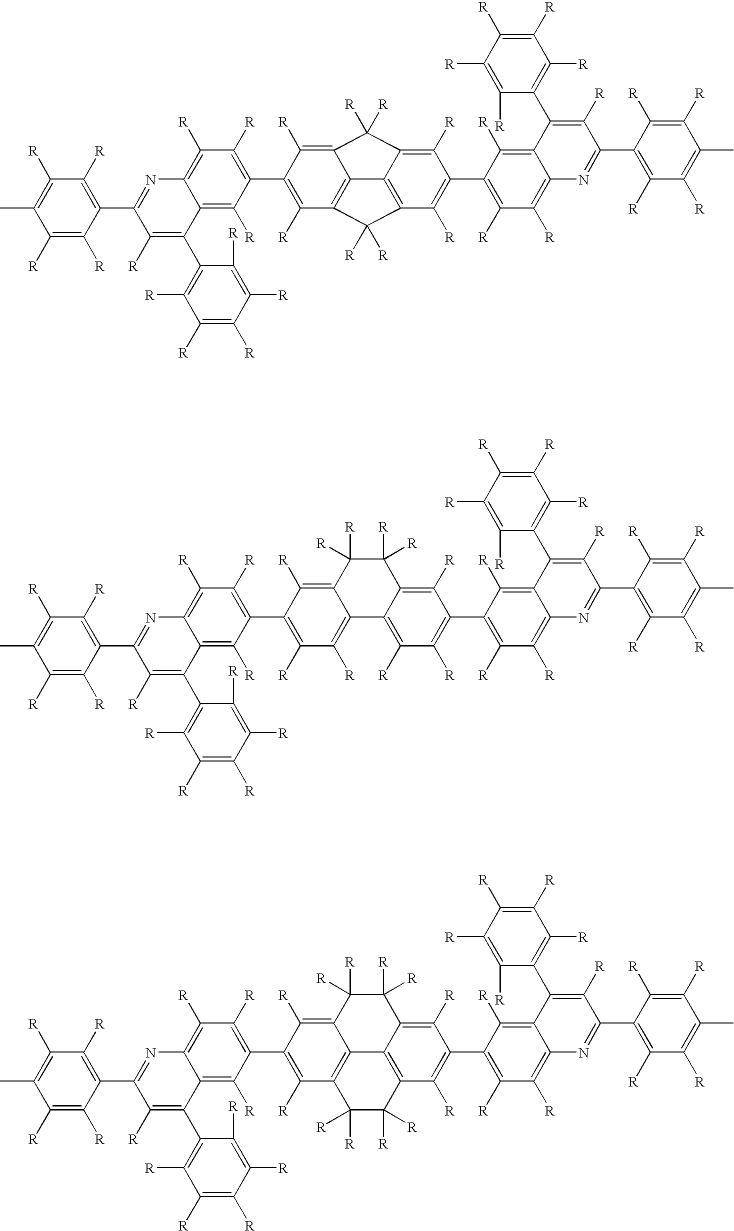

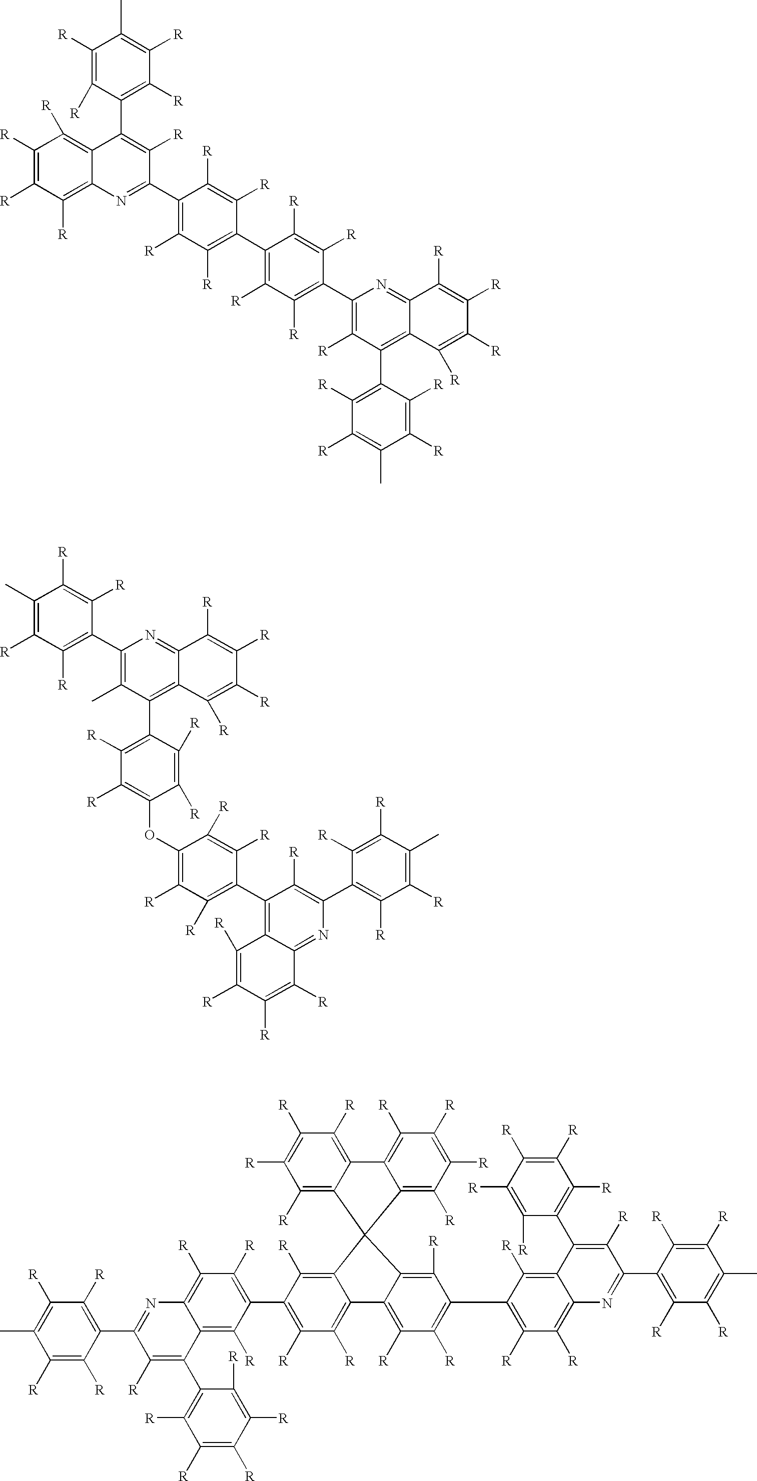

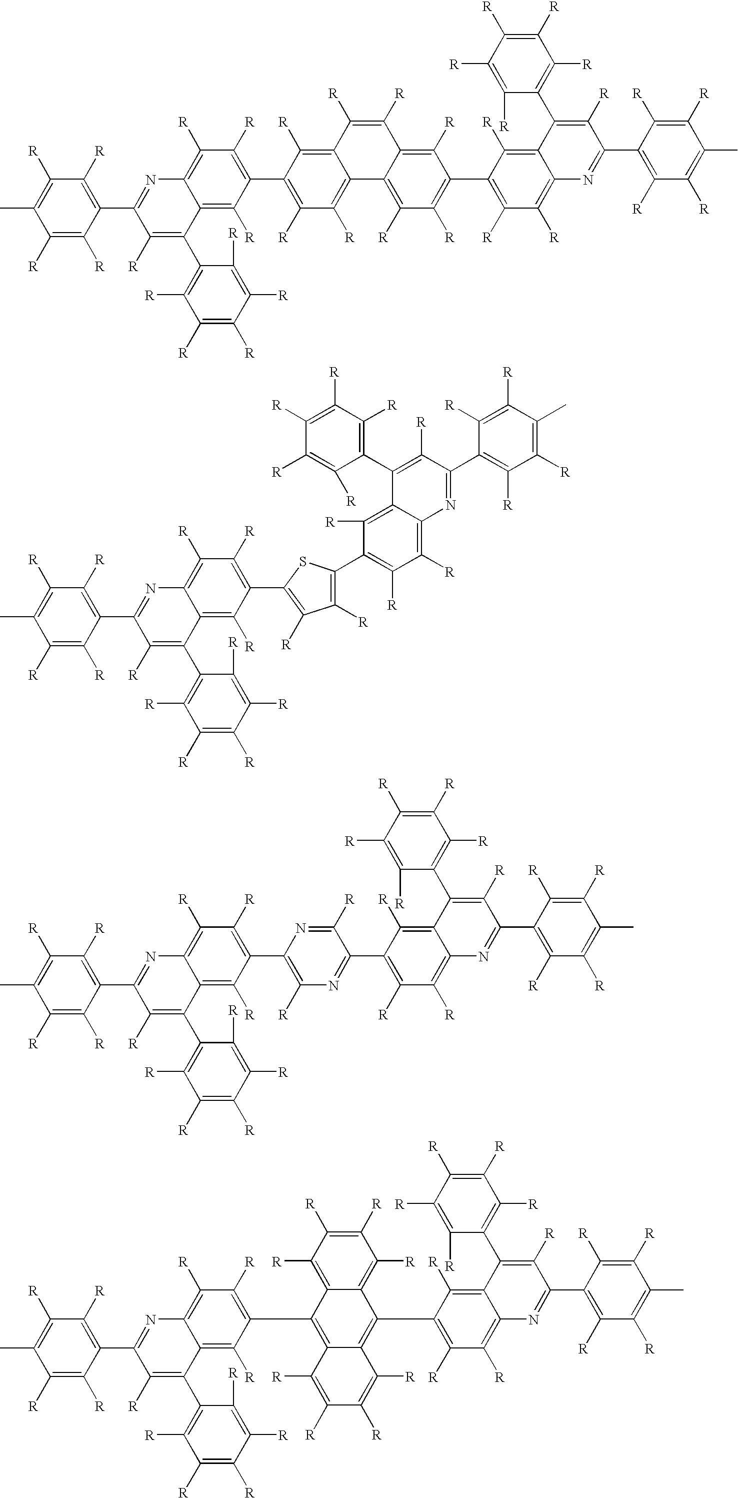

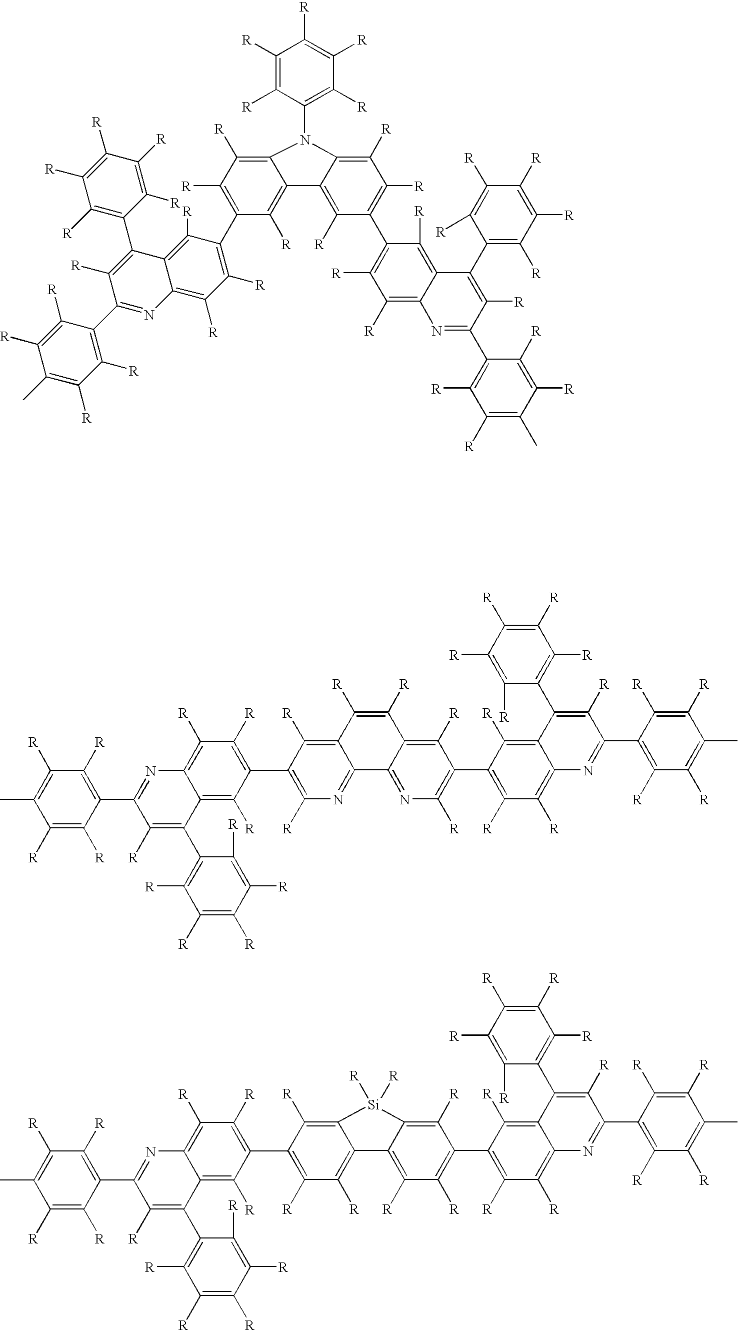

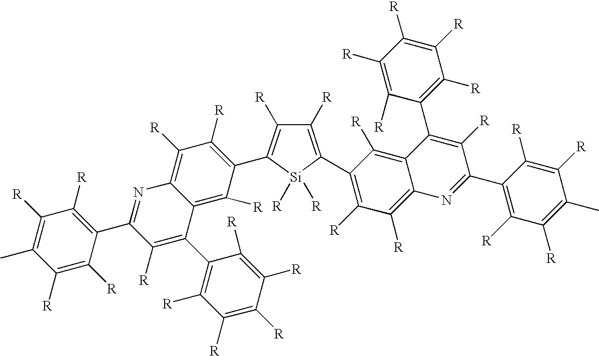

Here, in the above-mentioned quinoline monomer units, examples of the substituent R include substituents represented by the above-mentioned —R¹, —OR², —SR³, —OCOR⁴, —COOR⁵, —SiR⁶R⁷R⁸, or —NR⁹R¹⁰. R may be a hydrogen atom. The substituents R may be identical to or different from each other.

The benzotriazole monomer unit used in the present invention is preferably a benzotriazole represented by Formula (III), 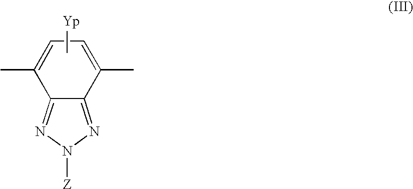
and these benzotriazole monomer units may be used singly or in a combination of two or more types.

In Formula (III), each Y and Z is independently a hydrogen atom or a monovalent organic residue.

It is preferable for the substituents Y in Formula (III) for the benzotriazole monomer unit to be independently substituents selected from the group consisting of a halogen atom, —R¹, —OR², —SR³, —OCOR⁴, —COOR⁵, and —SiR⁶R⁷R⁸ (here, R¹ to R⁸ are a C1 to C22 straight-chain, cyclic, or branched alkyl group or a C2 to C20 aryl or heteroaryl group), the substituents may be identical to or different from each other and are bonded to substitutable positions of the benzene ring of the benzotriazole skeleton, and p is an integer of 0 to 2.

The substituent Y may further have a substituent, and examples of the substituent include a substituent represented by the above-mentioned —R¹, —OR², —SR³, —OCOR⁴, —COOR⁵, —SiR⁶R⁷R⁸, or —NR⁹R¹⁰. When there are a plurality of substituents, the plurality of substituents may be identical to or different from each other.

Among these substituents, it is preferable for each Yp to be independently one in which p is 0, that is, there is no substituent, or one in which Y is a group represented by —R¹, and particularly preferably, from the viewpoint of polymerization reactivity and heat resistance, one which is directly substituted with an alkyl group.

Furthermore, in the benzotriazole unit of Formula (III), Z is preferably a group selected from the group consisting of optionally substituted alkyl, aryl, and heteroaryl groups. It is more preferable for Z to be a substituted or unsubstituted aryl group, and particularly preferably, from the viewpoint of various properties, phenyl.

Examples of a substituent on Z include a substituent represented by the above-mentioned —R¹, —OR², —SR³, —OCOR⁴, —COOR⁵, —SiR⁶R⁷R⁸, or —NR⁹R¹⁰ or furthermore, a halogen atom, or a C1 to C22 straight-chain, cyclic, or branched alkenyl group. When there are a plurality of substituents, the plurality of substituents may be identical to or different from each other.

As specific examples of the benzotriazole monomer unit of the present invention, example compounds are listed below, but they should not be construed as being limited thereto.

TABLE 1

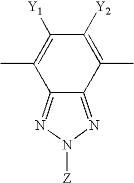

| Benzotriazole | | | |
|---|---|---|---|
| monomer No. | Y₁ | Y₂ | Z |
| (1) | H | H | 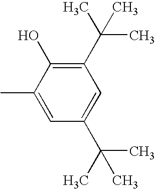 |
| (2) | H | H | 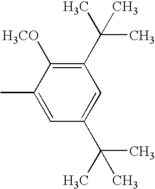 |
| (3) | H | H | 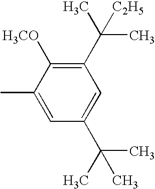 |
| (4) | H | H | 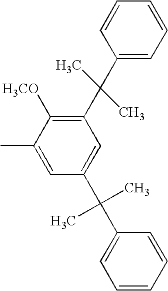 |
| (5) | H | H | 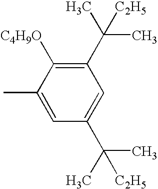 |
| (6) | H | H | 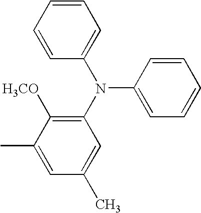 |
| (7) | H | H | 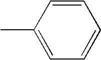 |
| (8) | H | H | 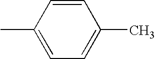 |
| (9) | H | H | 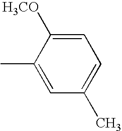 |
| (10) | H | H | 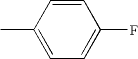 |
| (11) | H | H | 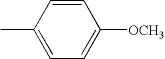 |
| (12) | H | H | 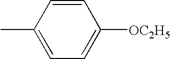 |
| (13) | H | H | 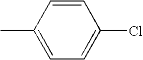 |
| (14) | H | H | 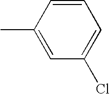 |
| (15) | H | H | 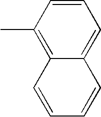 |
| (16) | H | H | 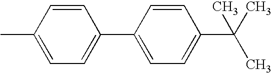 |
| (17) | H | H | 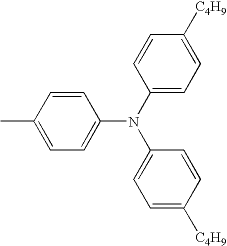 |
| (18) | H | H | 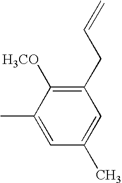 |
| (19) | H | H | 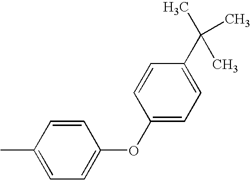 |
| (20) | H | H | 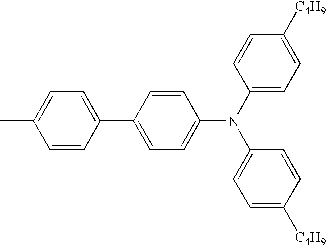 |
| (21) | OCH₃ | OCH₃ | 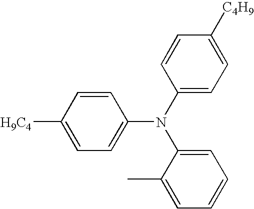 |
| (22) | 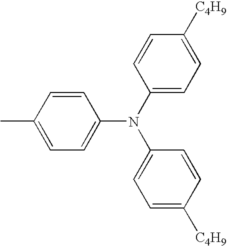 | H | 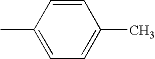 |
| (23) | 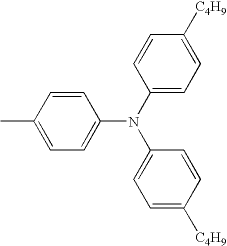 | H | 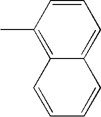 |
| (24) | 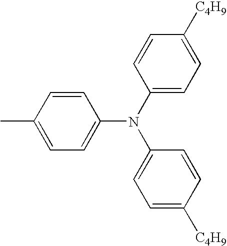 | H | 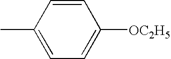 |
| (25) | Cl | H | 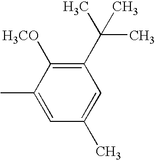 |
| (26) | CH₃ | H | 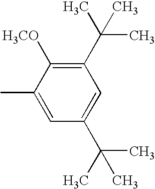 |
| (27) | CH₃ | CH₃ | 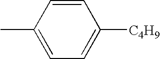 |
| (28) | 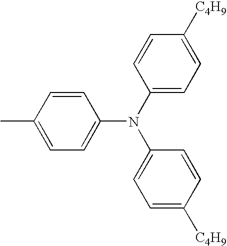 | H | 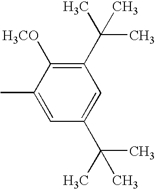 |
| (29) | 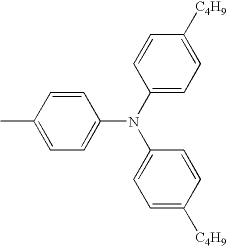 | H | 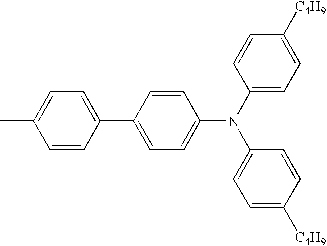 |
| (30) | H | H | C₆H₁₃ |
| (31) | H | H | 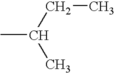 |
| (32) | H | H | 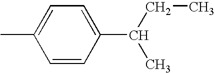 |
| (33) | H | H | 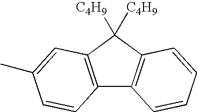 |
| (34) | H | H | 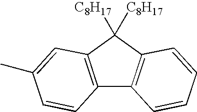 |
| (35) | H | H | 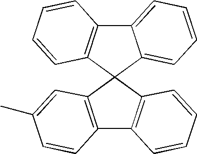 |
| (36) | H | H | 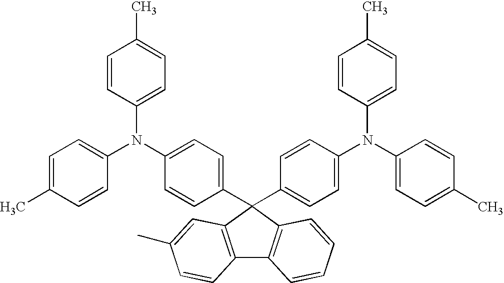 |
| (37) | H | H | 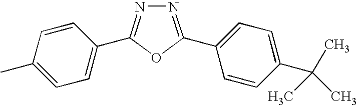 |
| (38) | H | H | 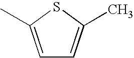 |
| (39) | H | H | 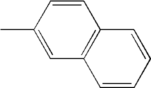 |
| (40) | H | H | 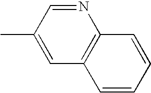 |
| (41) | H | H | 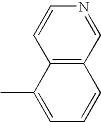 |
| (42) | H | H | 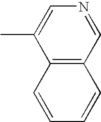 |
| (43) | H | H | 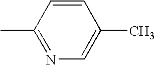 |
| (44) | H | H | 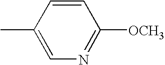 |
| (45) | H | H | 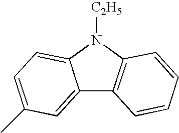 |
| (46) | H | H | 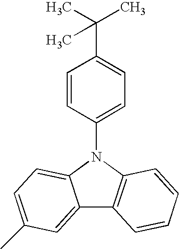 |
| (47) | H | H | 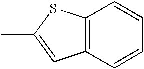 |
| (48) | SCH₃ | H | 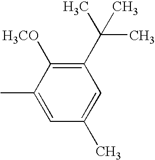 |
| (49) | OCOCH₃ | H | 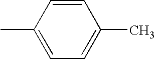 |
| (50) | COOC₄H₉ | H | 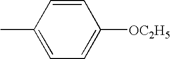 |
| (51) | Si(CH₃)₃ | H | 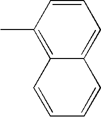 |
| (52) | H | H | 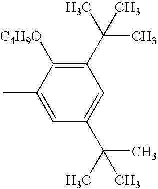 |

The quinoline copolymer of the present invention contains at least the above-mentioned two monomer units, and as necessary may contain a monomer unit other than the above monomer units as a ‘comonomer unit’. Examples of the ‘comonomer unit’ include a substituted or unsubstituted aromatic monomer unit, a substituted or unsubstituted heterocyclic monomer unit, and a monomer unit having a substituted or unsubstituted triphenylamine skeleton. Examples of the aromatic monomer unit and the heterocyclic monomer unit include benzene, biphenyl, terphenyl, naphthalene, anthracene, tetracene, phenanthrene, stilbene, chrysene, pyridine, pyrazine, isoquinoline, acridine, phenanthroline, furan, pyrrole, thiophene, diphenyloxadiazole, benzothiazole, diphenyldiazole, and diphenylthiadiazole; and examples of the monomer unit having the triphenylamine skeleton include triphenylamine, N-(4-butylphenyl)-N,N-diphenylamine, N,N′-diphenyl-N,N′-bis(3-methylphenyl)-[1,1′-biphenyl]-4,4′-diamine, and N,N′-bis(3-methylphenyl)-N,N′-bis(2-naphthyl)-[1,1′-biphenyl]-4,4′-diamine and, furthermore, there can also be cited a branched structure monomer and alkynylene.

The comonomer unit may be substituted with the above-mentioned organic residue. Examples of substituents that the comonomer unit may have include substituents represented by —R¹, —OR², —SR³, —OCOR⁴, —COOR⁵, —SiR⁶R⁷R⁸, or —NR⁹R¹⁰. When there are a plurality of substituents, the plurality of substituents may be identical to or different from each other.

As specific examples of the comonomer unit of the present invention, example compounds are listed below, but they should not be construed as being limited thereto.

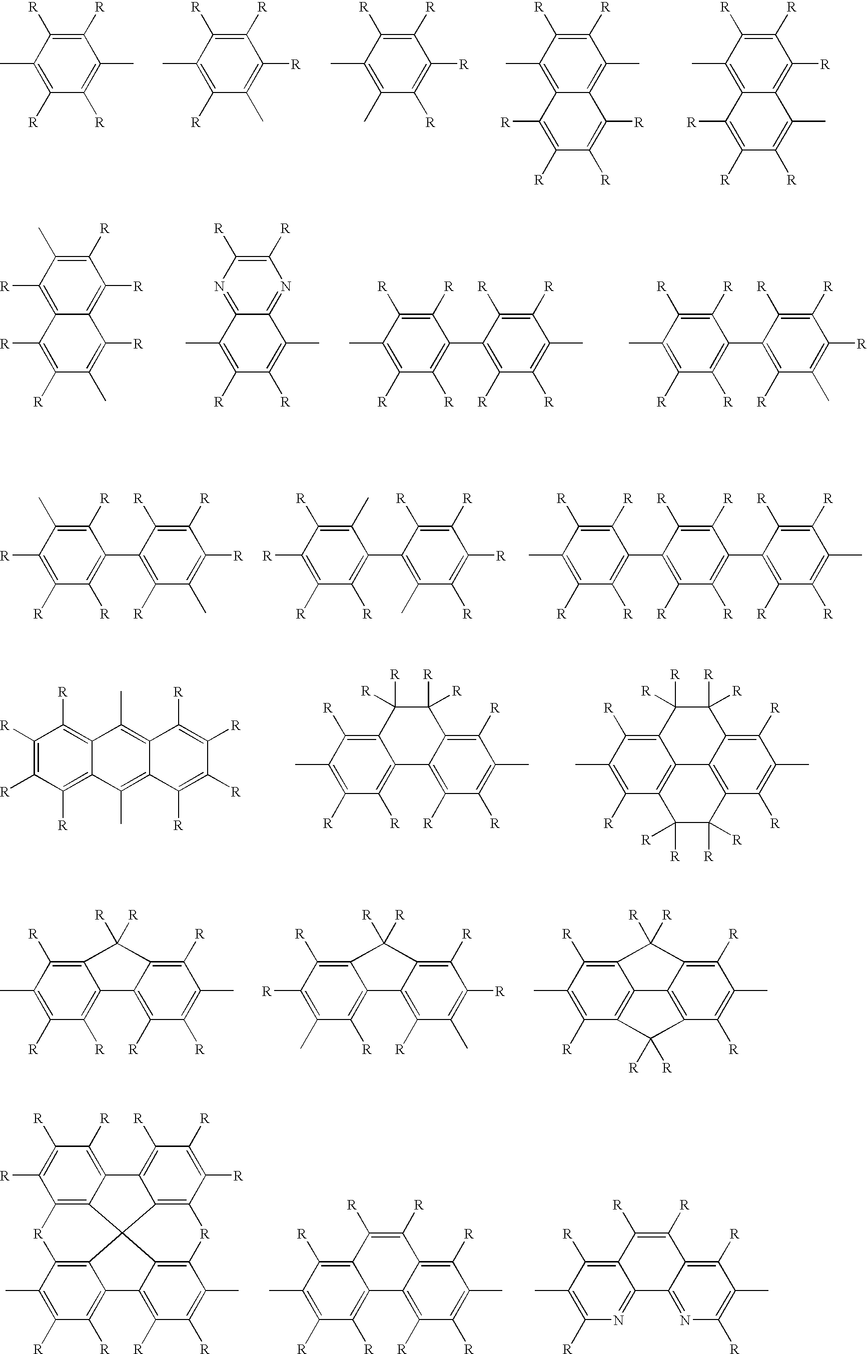

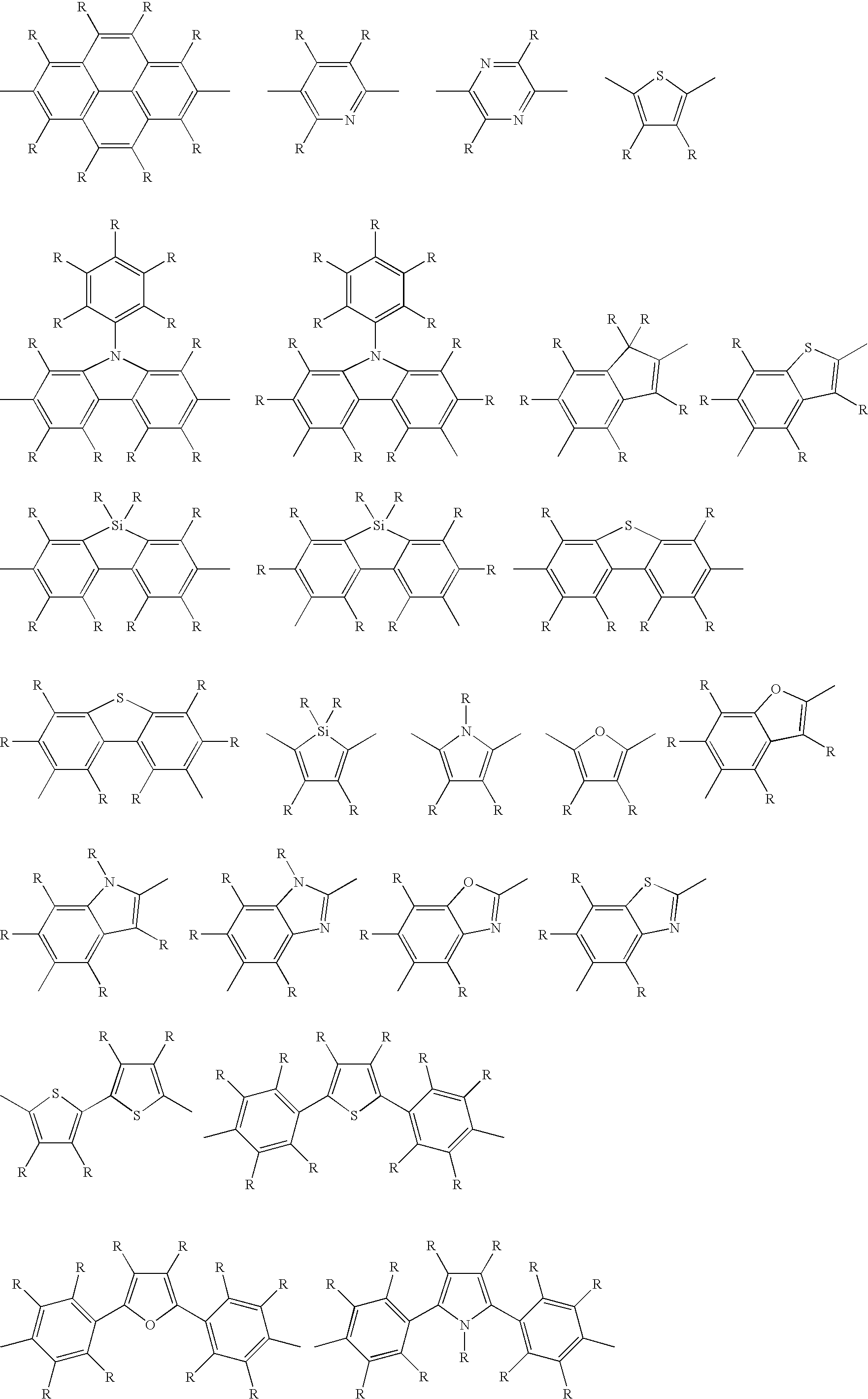

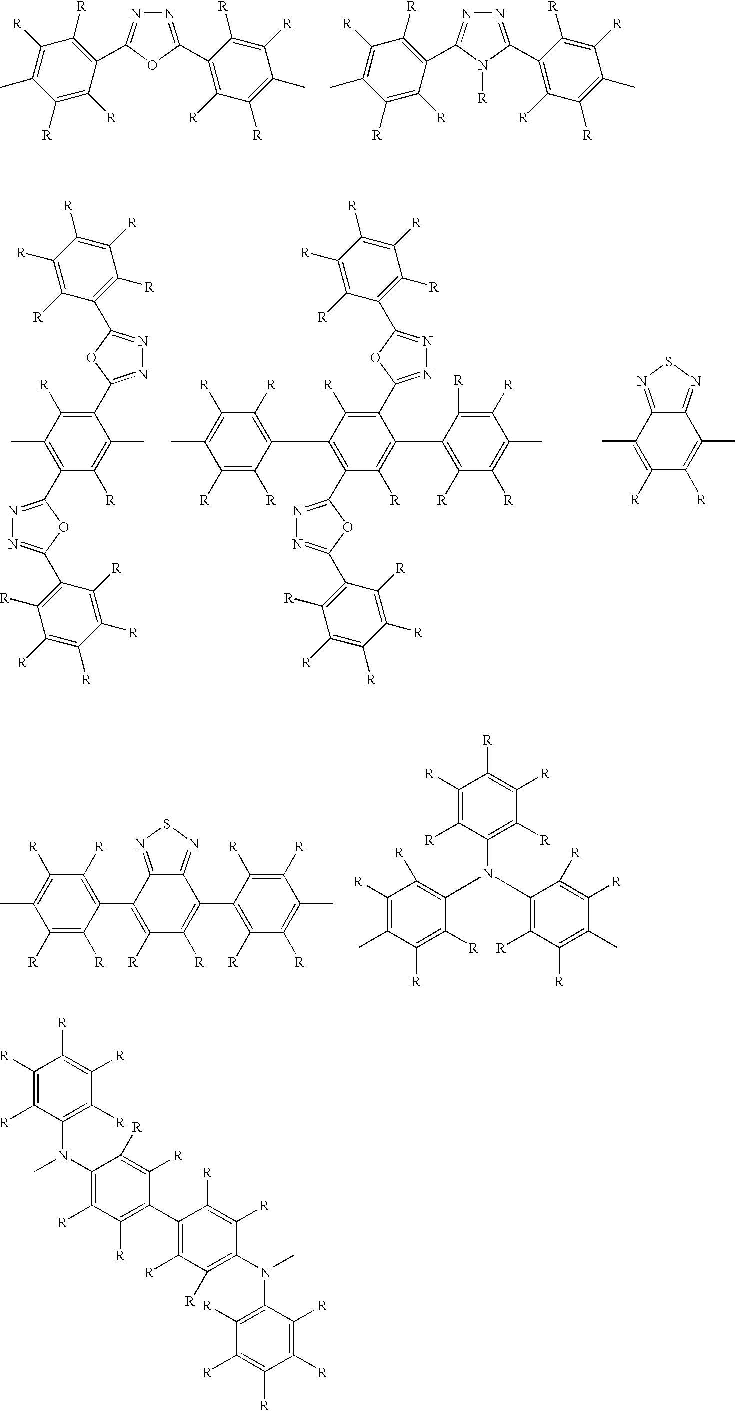

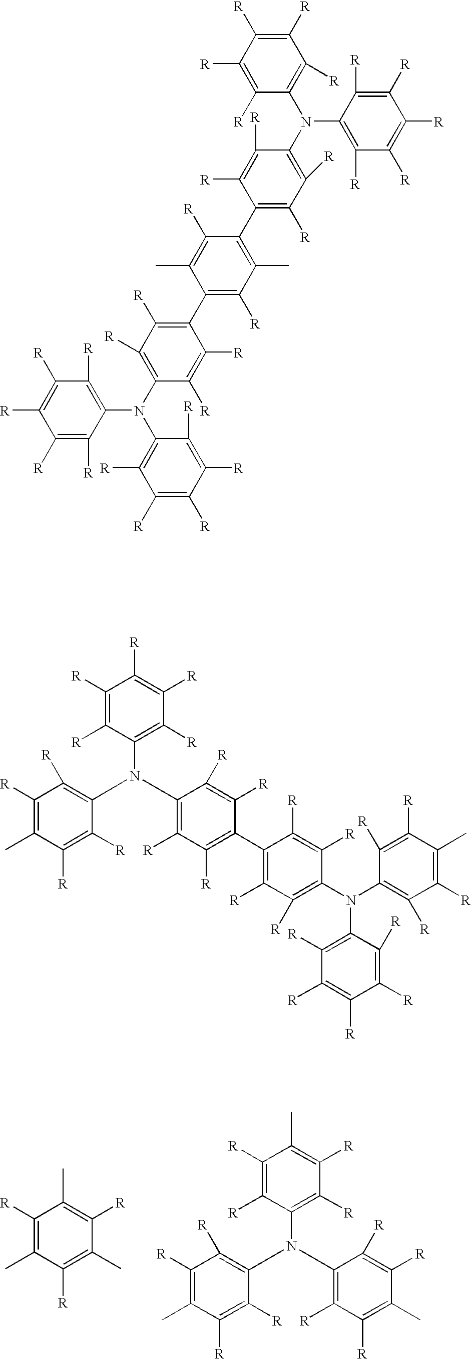

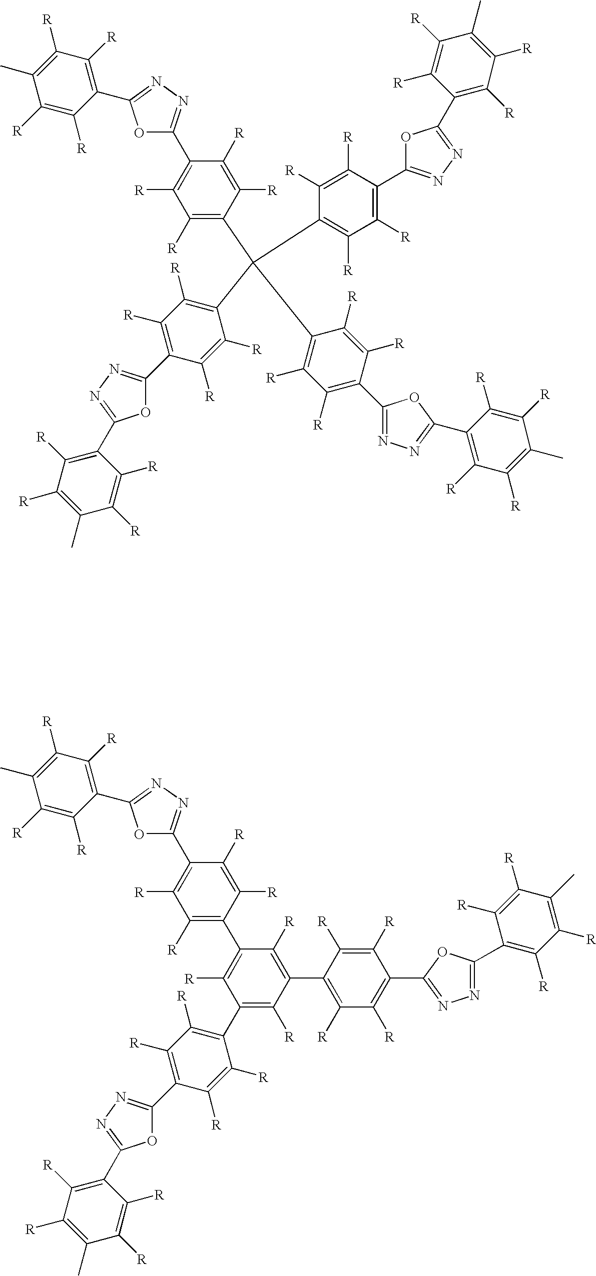

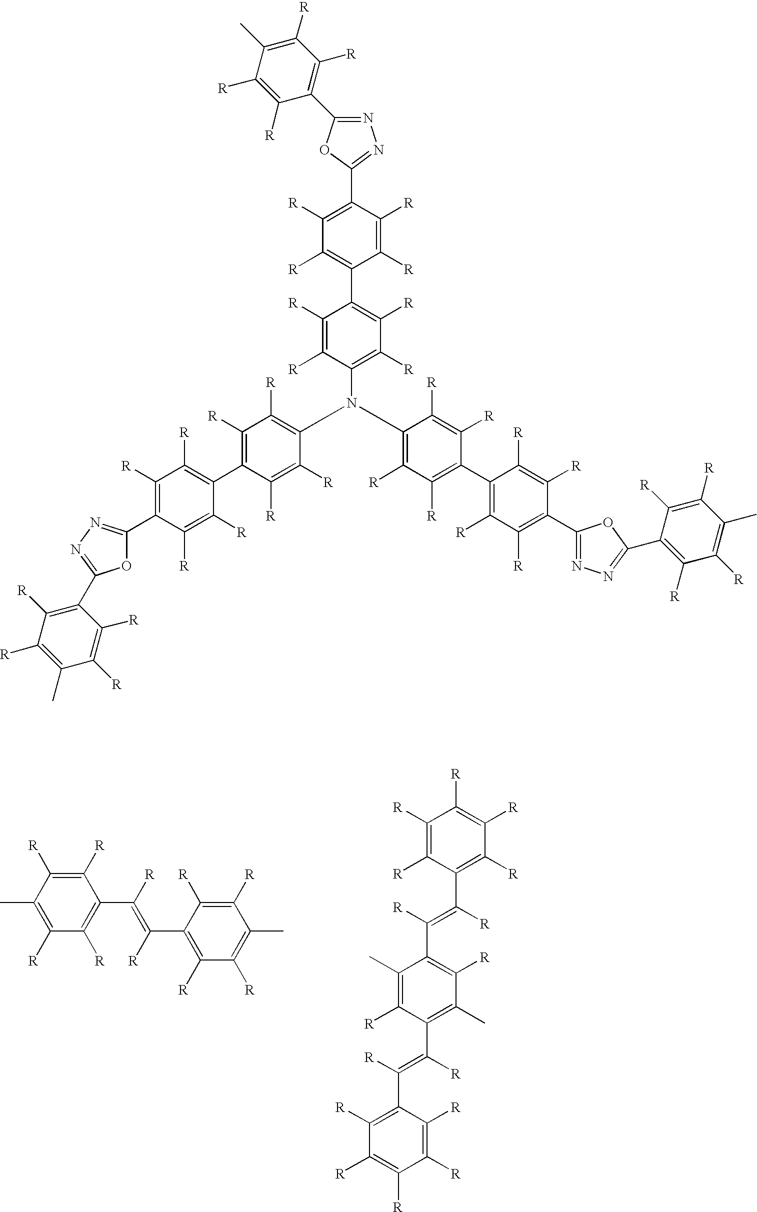

In the above-mentioned comonomer units, examples of the substituents R include substituents represented by the above-mentioned —R¹, —OR², —SR³, —OCOR⁴, —COOR⁵, —SiR⁶R⁷R⁸, or —NR⁹R¹⁰. R may be a hydrogen atom. The substituents R may be identical to or different from each other.

The quinoline copolymer of the present invention preferably has a linking group represented by Formula (II):
-(D) b- (II)
as a group linking the above-mentioned monomer units.

In Formula (II), D is a divalent organic residue, and is preferably —O—, —S—, —NR—, —CR₂—, —SiR₂—, —SiR₂—O—SiR₂—, or —SiR₂—O—SiR₂—O—SiR₂—, and each R independently a hydrogen atom, a C1 to C22 straight-chain, cyclic, or branched alkyl group, or a C2 to C20 aryl or heteroaryl group. b is an integer of 0 to 1.

In the above-mentioned Formula (II), when b is 0, it means a single bond. Among these, the linking group is preferably a single bond or —O—, from the viewpoint of ease of synthesis. R is preferably a C1 to C22 straight-chain, cyclic, or branched alkyl group from the viewpoint of imparting solubility, and particularly preferably, from the viewpoint of polymerization reactivity, a C1 to C6 straight-chain alkyl group.

In the present invention, the quinoline copolymer is preferably a copolymer containing at least a quinoline monomer unit represented by Formulae (I) and a benzotriazole unit represented by Formula (III), a group linking each of the monomer units being represented by Formula (II).

The mole fraction of the quinoline monomer unit relative to the total number of monomer units of the quinoline copolymer of the present invention is preferably 1% to 99%, more preferably 3% to 97%, and most preferably 5% to 95%. When the quinoline monomer unit is present at less than 1%, the luminescence chromaticity tends to deteriorate, and when it exceeds 99%, the luminance tends to decrease.

The mole fraction of the benzotriazole monomer unit relative to the total number of monomer units of the quinoline copolymer of the present invention is preferably 1% to 99%, more preferably 3% to 97%, and most preferably 5% to 95%. When the benzotriazole monomer unit is present at less than 1%, the luminance tends to decrease, and when it exceeds 99%, the luminescence chromaticity tends to deteriorate.

The mole fraction of the comonomer unit, such as an aromatic monomer unit, a substituted or unsubstituted heterocyclic monomer unit, or a monomer unit having a substituted or unsubstituted triphenylamine skeleton that can be copolymerized with the quinoline copolymer of the present invention is preferably 0% to 80% of the total number of monomer units of the polymer, more preferably 0% to 50%, and yet more preferably 0% to 30%. Use of the comonomer unit is preferable from the viewpoint of polymerization reactivity. When the comonomer unit content exceeds 80%, the properties tend to deteriorate.

The quinoline copolymer of the present invention can be produced by various synthetic methods known to a person skilled in the art. For example, when there is no group linking each of the monomer units, that is, when b in Formula (II) is 0, methods reported by T. Yamamoto et al. in Bull. Chem. Soc. Jap., Vol. 51, No. 7, p. 2091 (1978), and by M. Zembayashi et al. in Tet. Lett., Vol. 47, p. 4089 (1977) can be employed. In particular, a method reported by Suzuki in Synthetic Communications, Vol. 11, No. 7, p. 513 (1981) is generally used for production of a copolymer. This reaction involves a Pd-catalyzed cross-coupling reaction between an aromatic boronic acid derivative and an aromatic halide (normally called the ‘Suzuki reaction’), and enables the quinoline copolymer of the present invention to be produced by a reaction that links the respective aromatic rings together.

This reaction normally employs a soluble Pd compound in the form of a Pd(II) salt or a Pd(0) complex. As the Pd source, 0.01 to 5 mol %, relative to the aromatic reactants, of Pd(PPh₃)₄, a complex between a tertiary phosphine ligand and Pd(OAc)₂, or a PdCl₂(dppf) complex is generally preferable. This reaction also employs a base, and an aqueous alkali carbonate or bicarbonate is most preferable. The reaction can be promoted by the use of a phase-transfer catalyst in a nonpolar solvent. As the solvent, N,N-dimethylformamide, toluene, dimethoxyethane, tetrahydrofuran, etc. can be used.

In the case of the polymer of the present invention, specifically, for example, it can be produced by copolymerization of a diboronic acid ester of a quinoline derivative represented by the formulae below 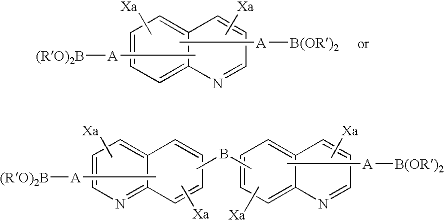
(in the formulae, R′ is a lower alkyl group such as methyl, ethyl, or propyl, or a lower alkylene group such as ethylene or propylene in which two R′ groups are bonded to each other to form a ring, and X, A, B, and a are as described above) with a dibromobenzotriazole derivative and, as necessary, a boronic acid ester comonomer or a bromide comonomer that can be copolymerized therewith, in the presence of a palladium (0) catalyst using a water-soluble base. It can also be produced by copolymerization of a dibromoquinoline derivative, a dibromobenzotriazole derivative, and a boronic acid ester comonomer that can be copolymeized therewith, in the presence of a palladium (0) catalyst using a water-soluble base.

As specific examples of the quinoline copolymer of the present invention, example compounds are listed below, but they should not be construed as being limited thereto.

TABLE 2

| Polymer | Diboronic acid ester monomer |
|---|---|
| (1) | 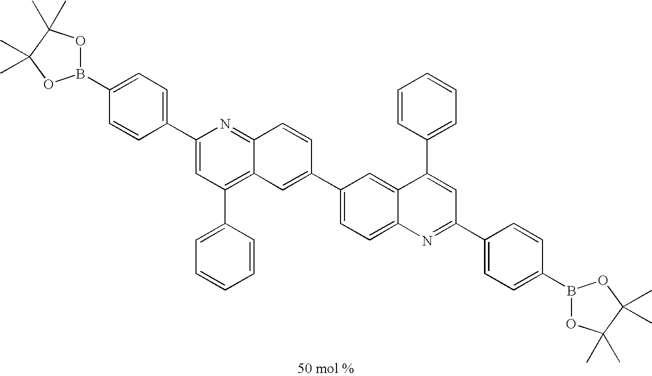 |
| (2) | 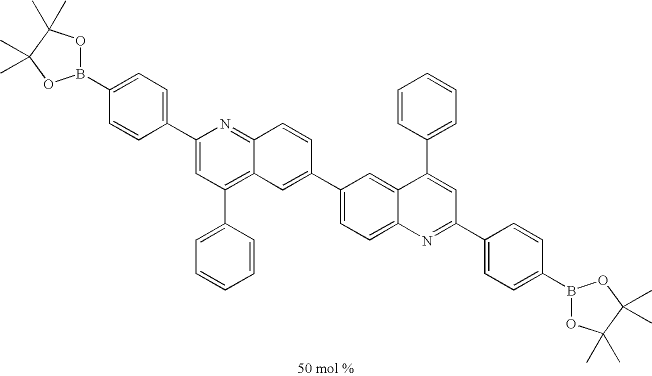 |
| (3) | 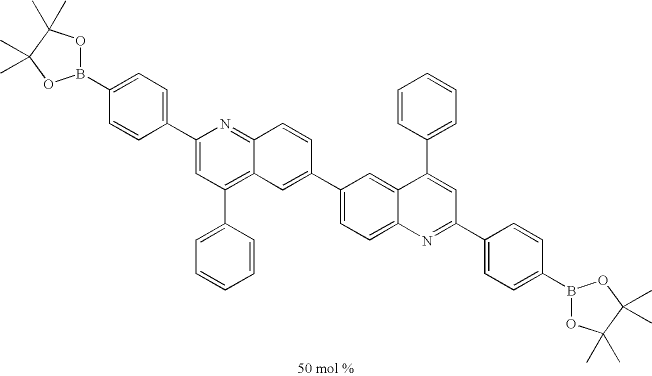 |
| (4) | 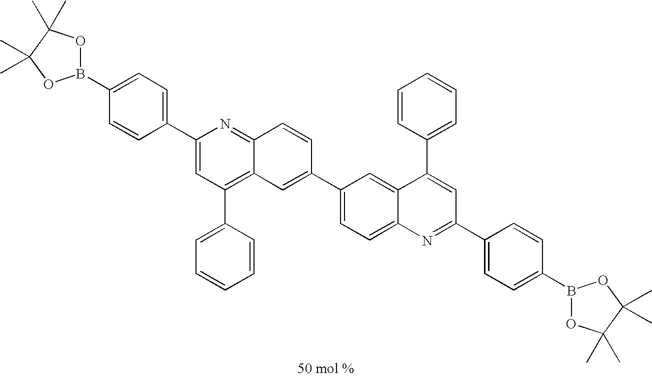 |
| (5) | 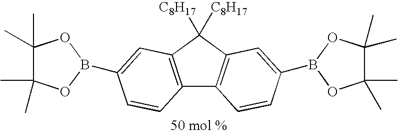 |
| (6) | 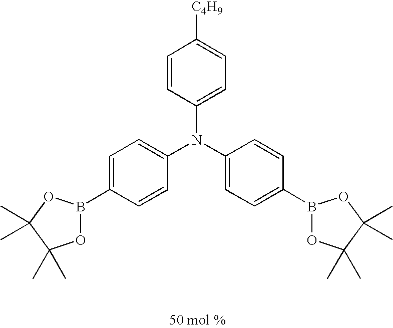 |
| (7) | 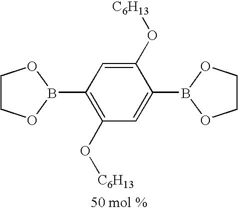 |
| (8) | 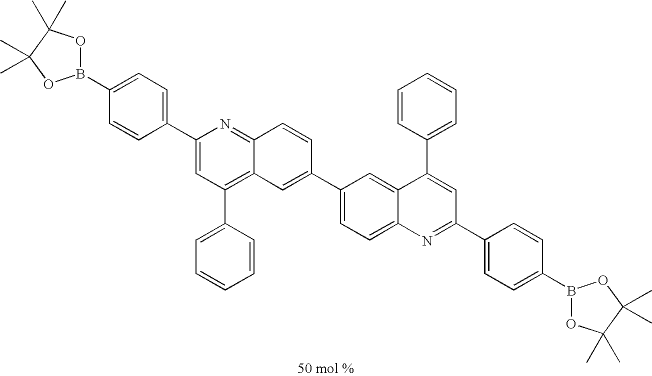 |
| (9) | 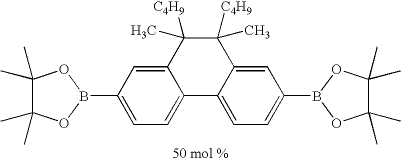 |
| (10) | 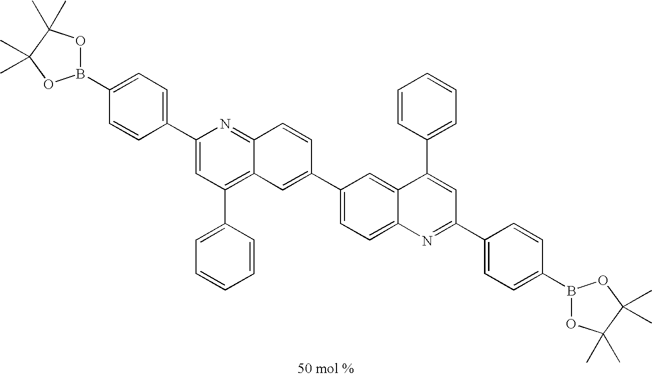 |
| (11) | 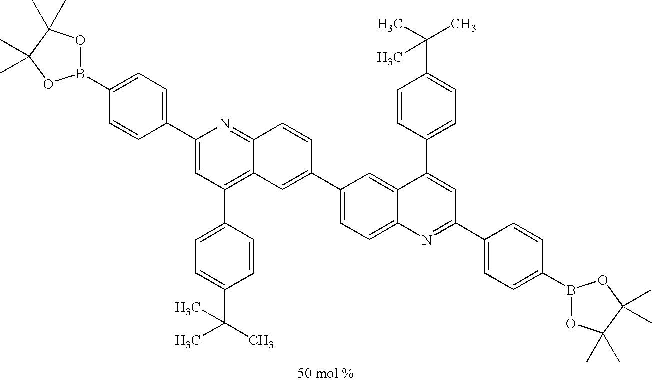 |
| (12) | 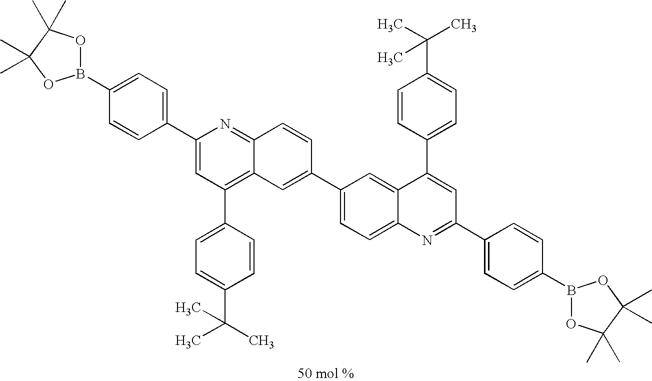 |
| (13) | 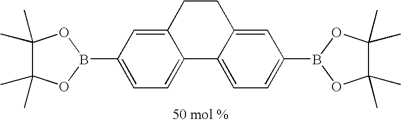 |
| (14) | 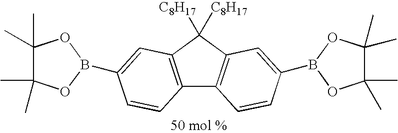 |
| (15) | 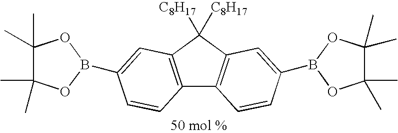 |
| (16) | 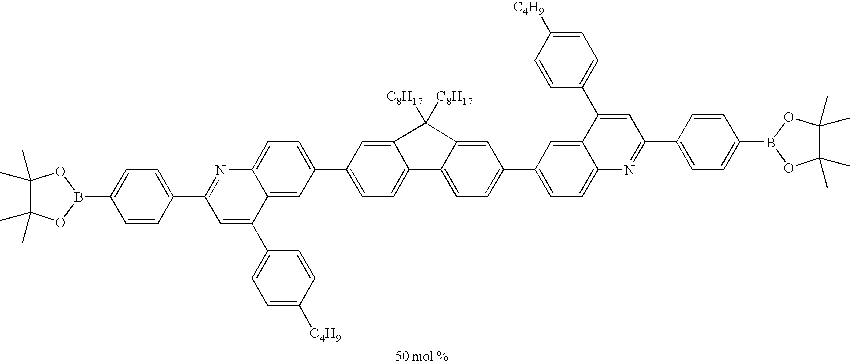 |
| (17) | 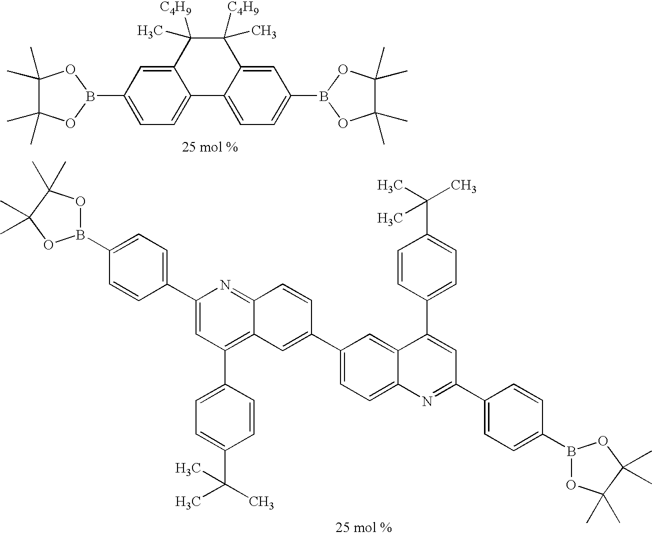 |
| (18) | 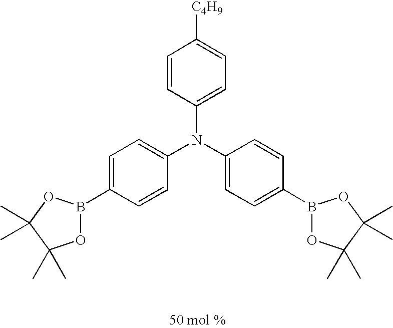 |
| (19) | 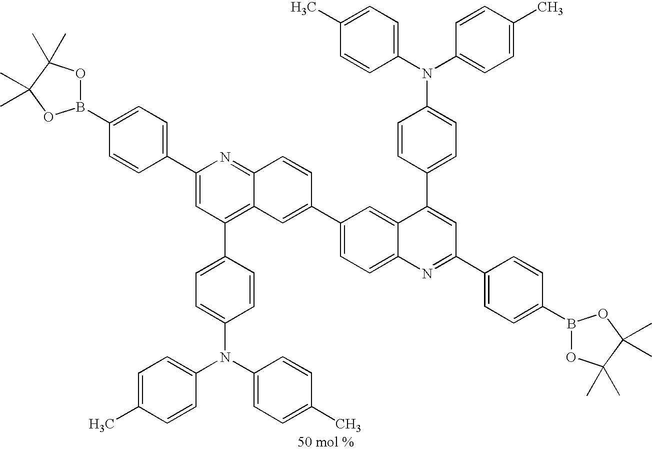 |
| (20) | 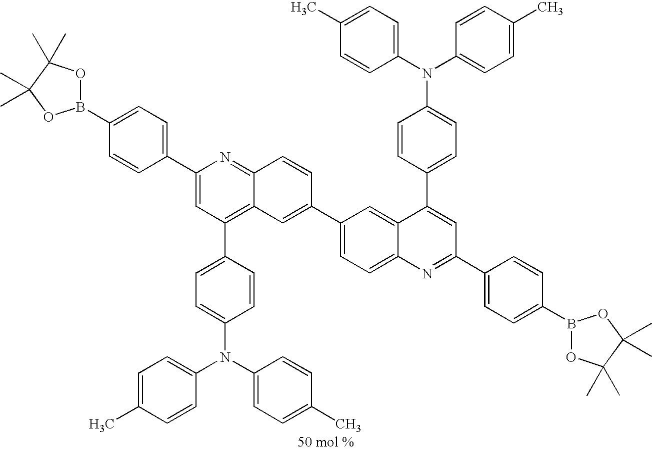 |
| (21) | 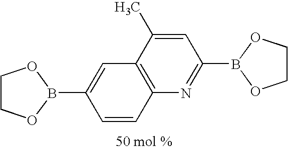 |
| (22) | 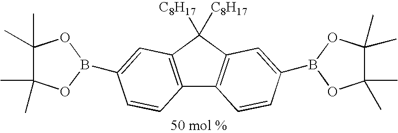 |
| (23) | 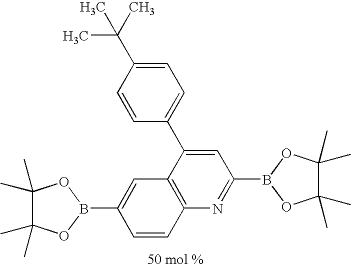 |
| (24) | 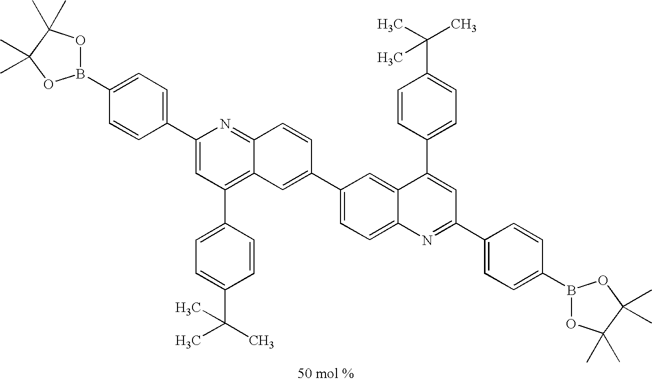 |
| (25) | 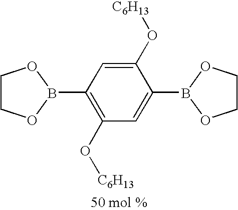 |
| (26) | 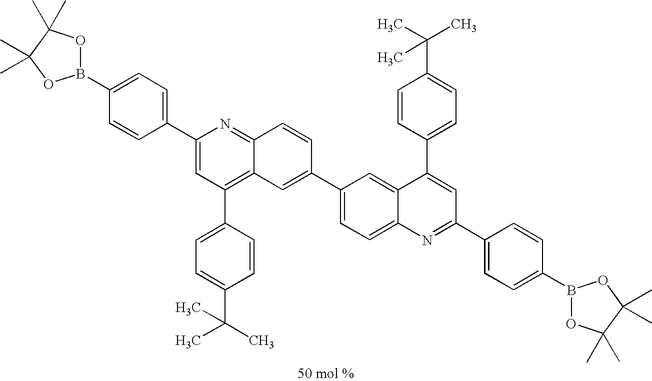 |
| (27) | 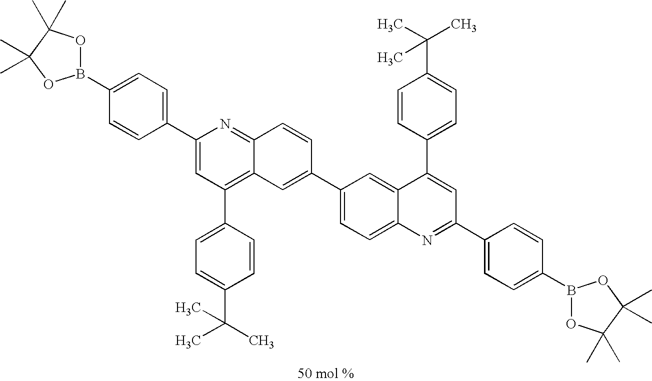 |
| (28) | 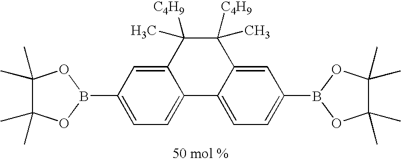 |
| (29) | 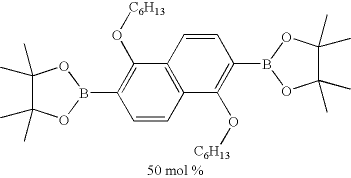 |
| (30) | 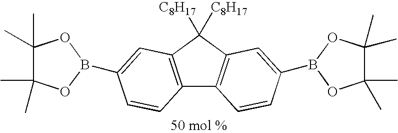 |
| (31) | 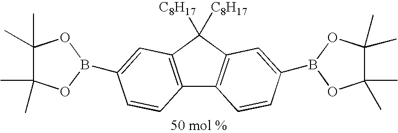 |
| (32) | 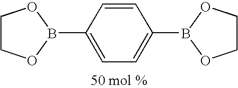 |
| (33) | 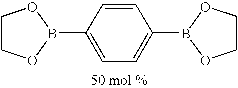 |
| (34) | 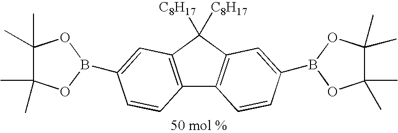 |
| (35) | 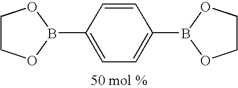 |

| Polymer | Dibromo monomer |
|---|---|
| (1) | 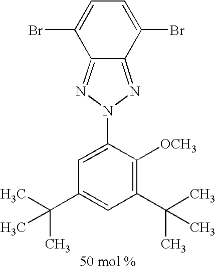 |
| (2) | 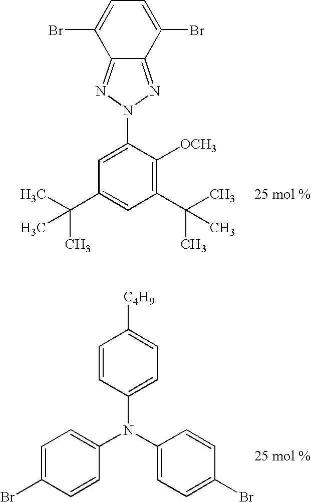 |
| (3) | 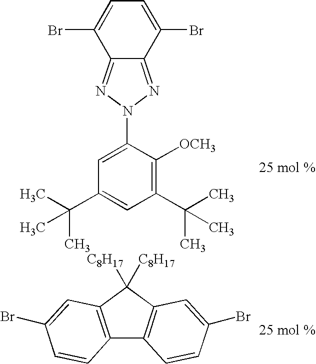 |
| (4) | 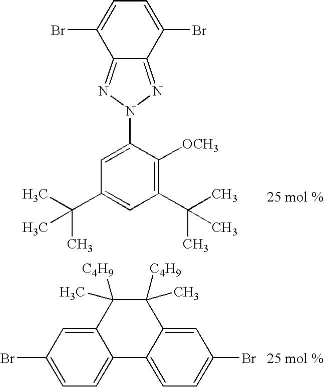 |
| (5) | 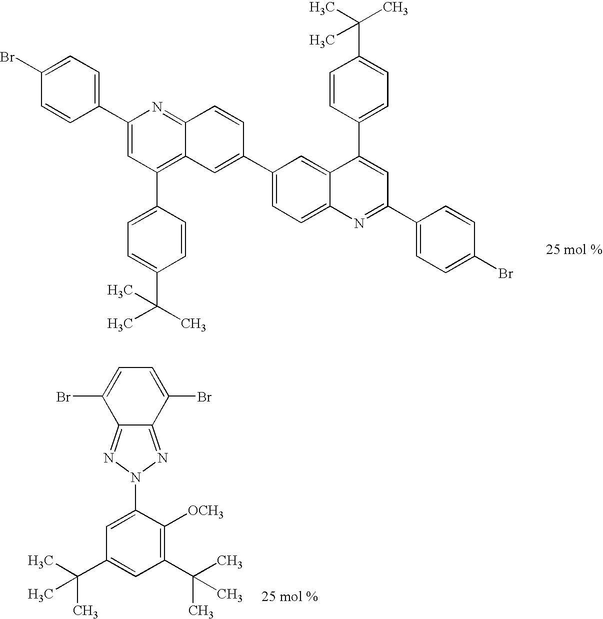 |
| (6) | 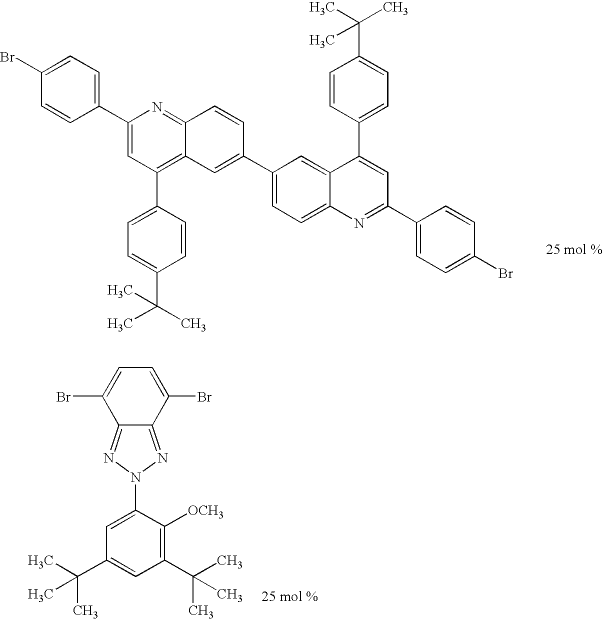 |
| (7) | 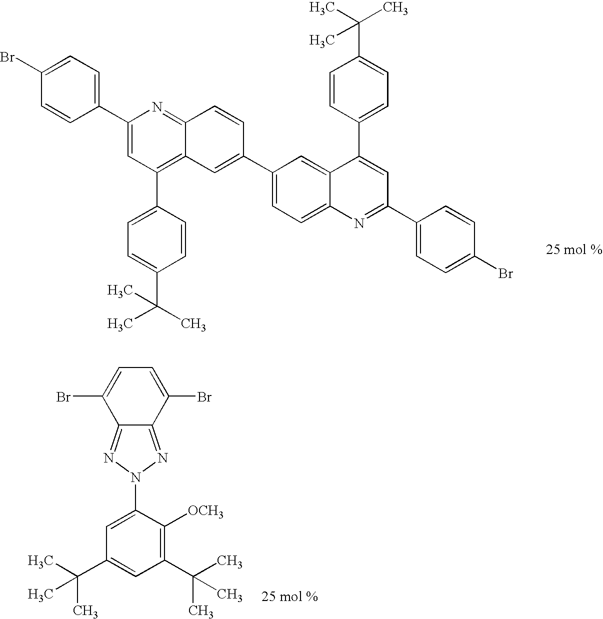 |
| (8) | 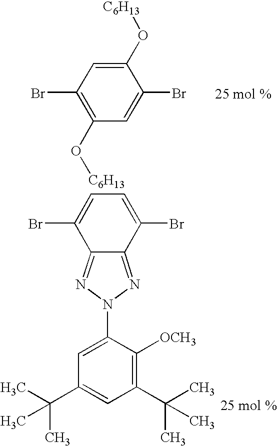 |
| (9) | 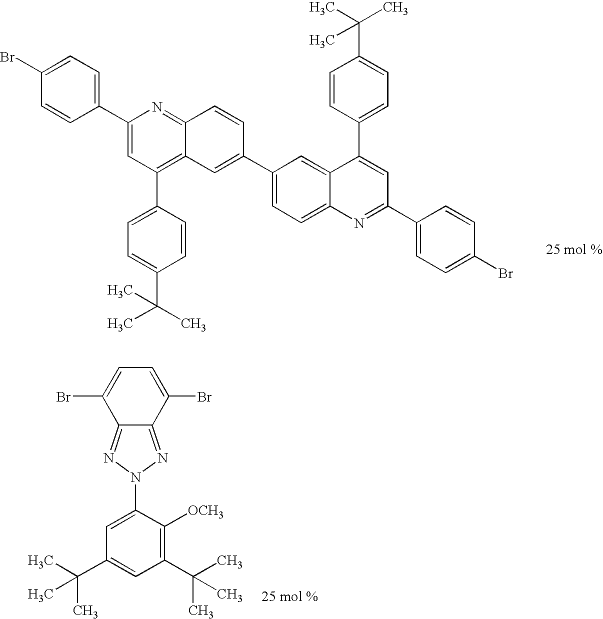 |
| (10) | 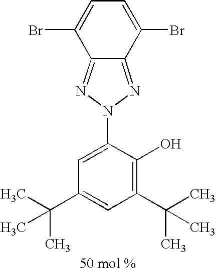 |
| (11) | 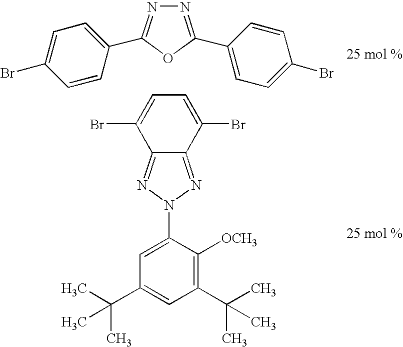 |
| (12) | 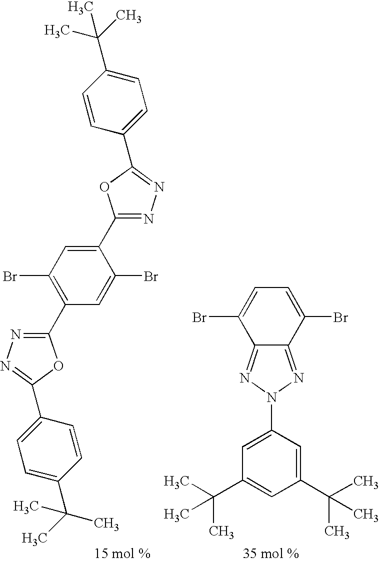 |
| (13) | 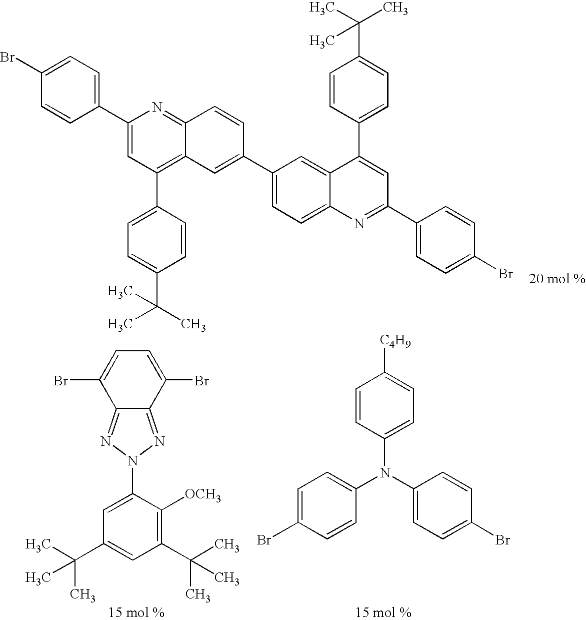 |
| (14) | 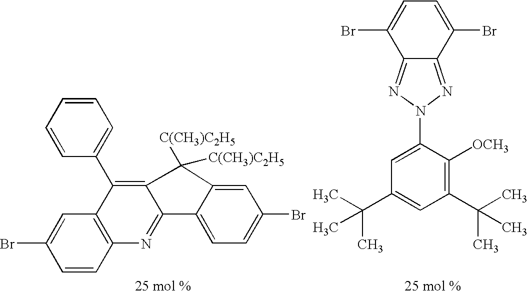 |
| (15) | 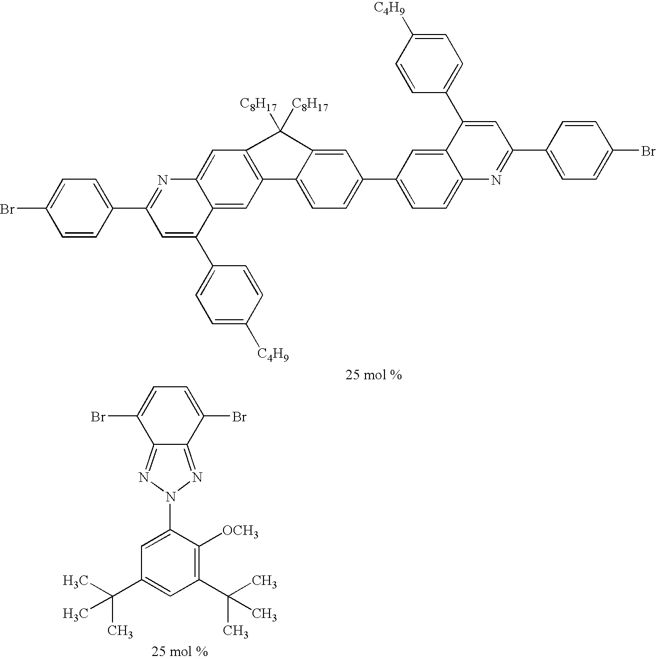 |
| (16) | 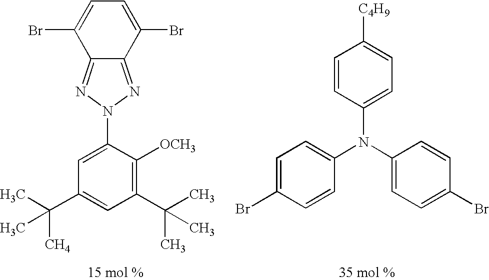 |
| (17) | 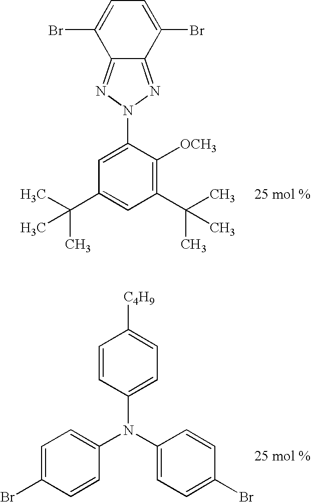 |
| (18) | 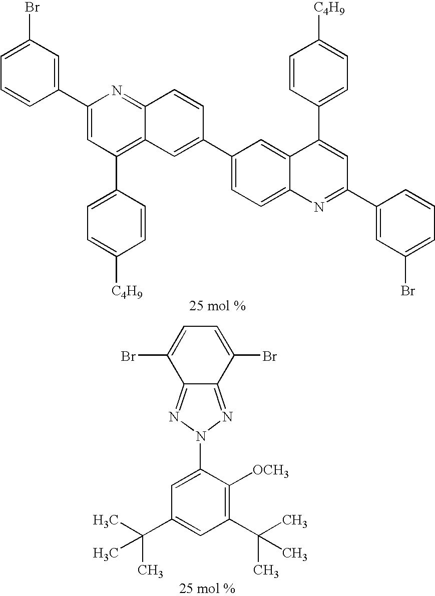 |
| (19) | 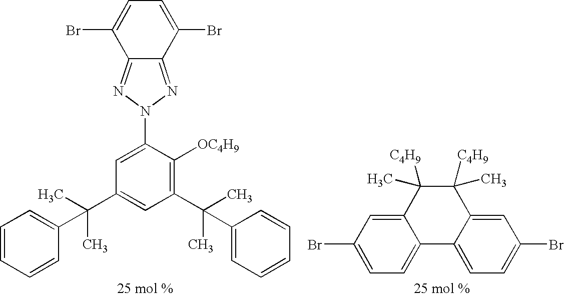 |
| (20) | 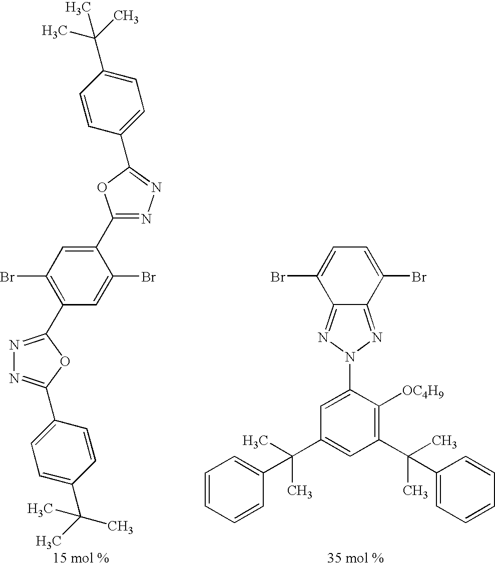 |
| (21) | 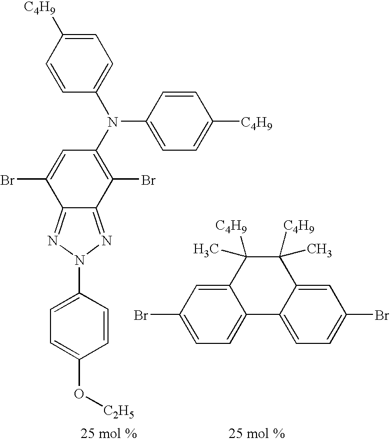 |
| (22) | 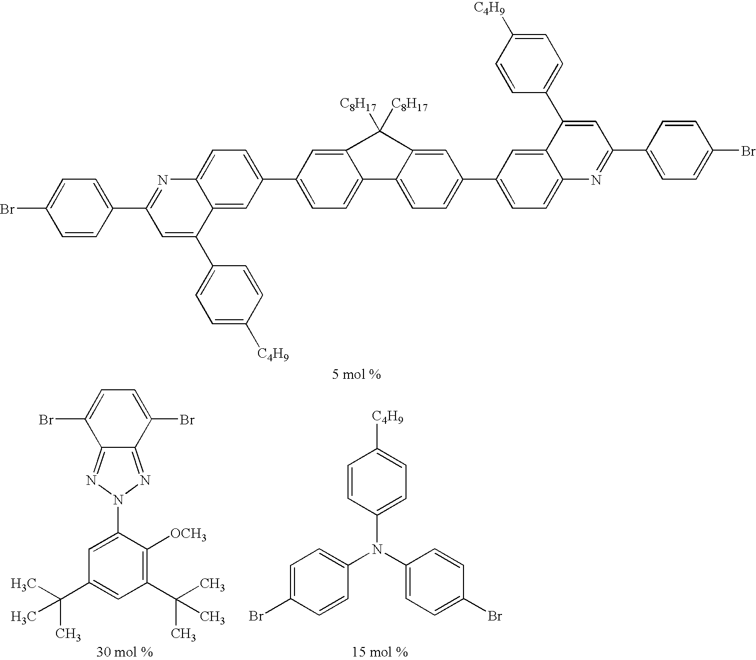 |
| (23) | 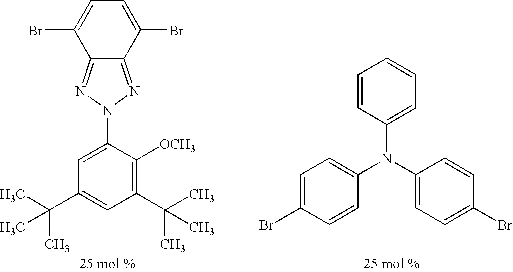 |
| (24) | 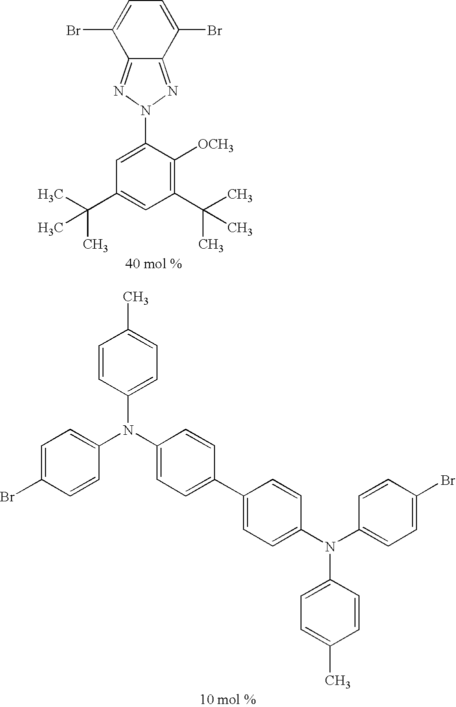 |
| (25) | 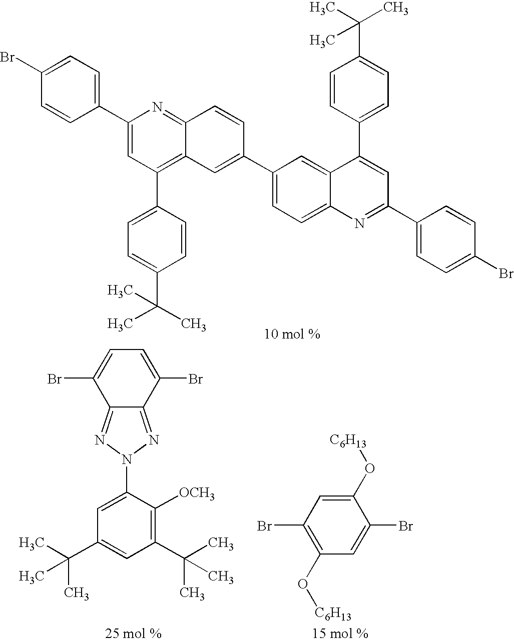 |
| (26) | 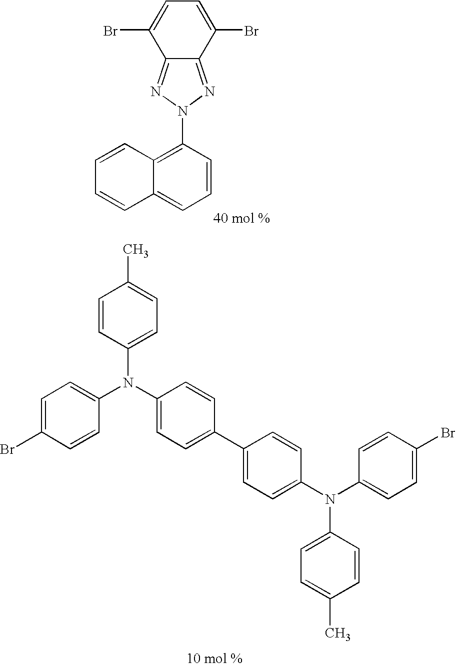 |
| (27) | 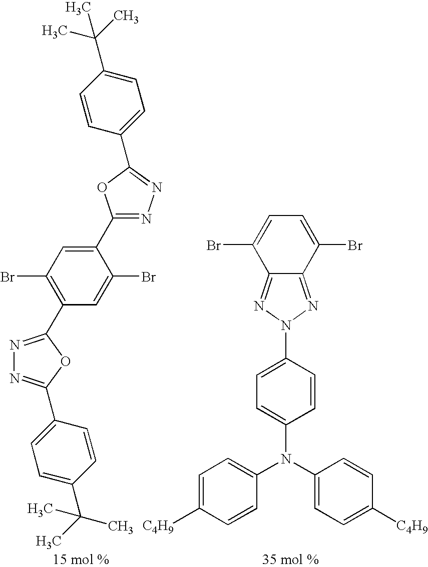 |
| (28) | 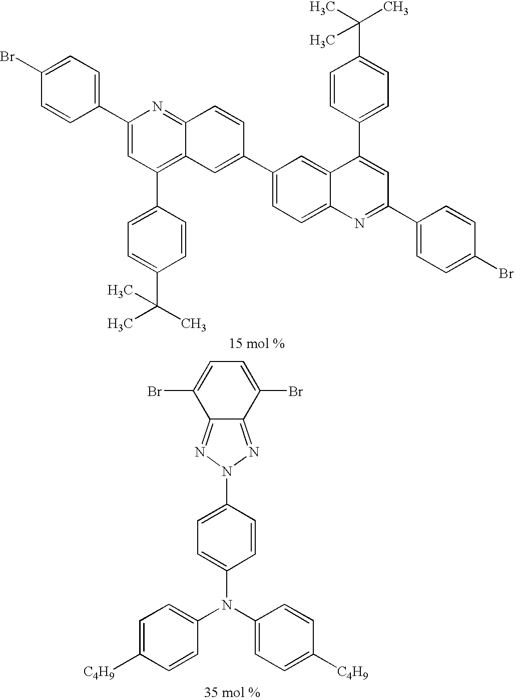 |
| (29) | 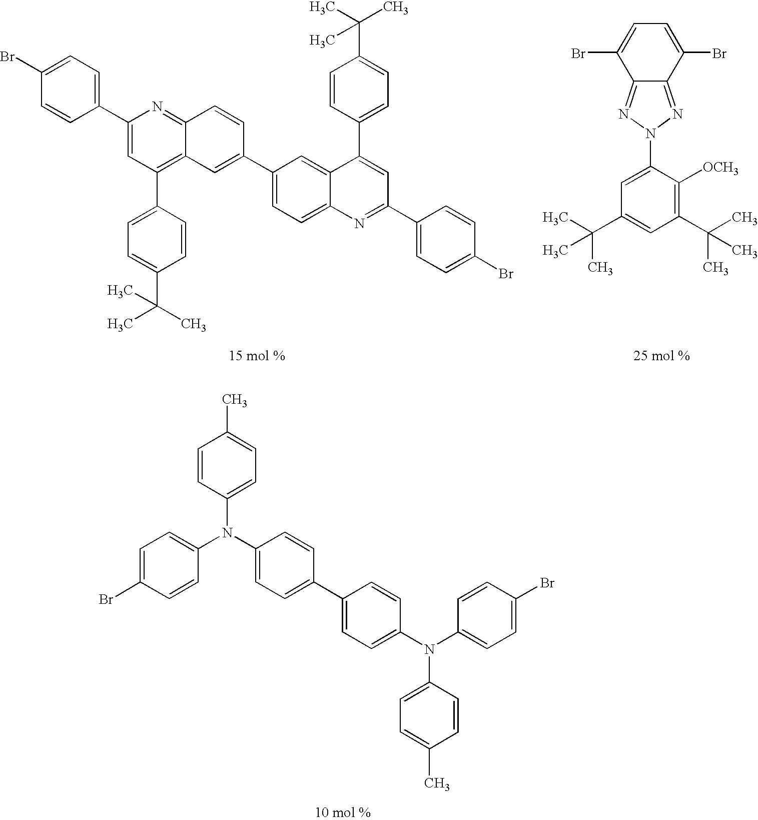 |
| (30) | 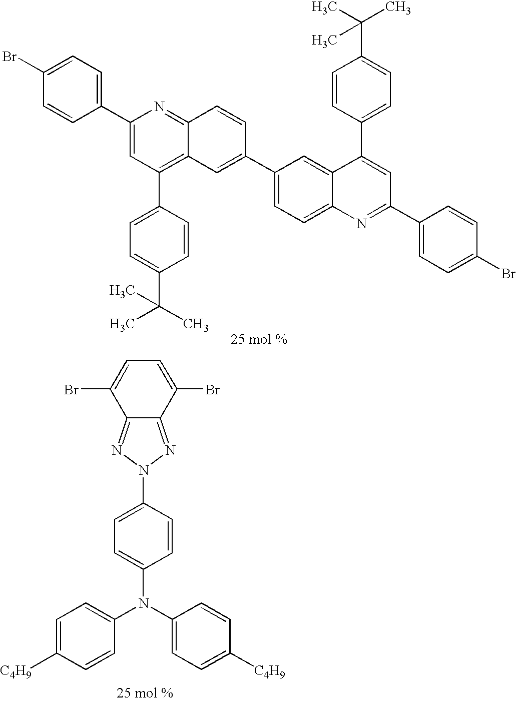 |
| (31) | 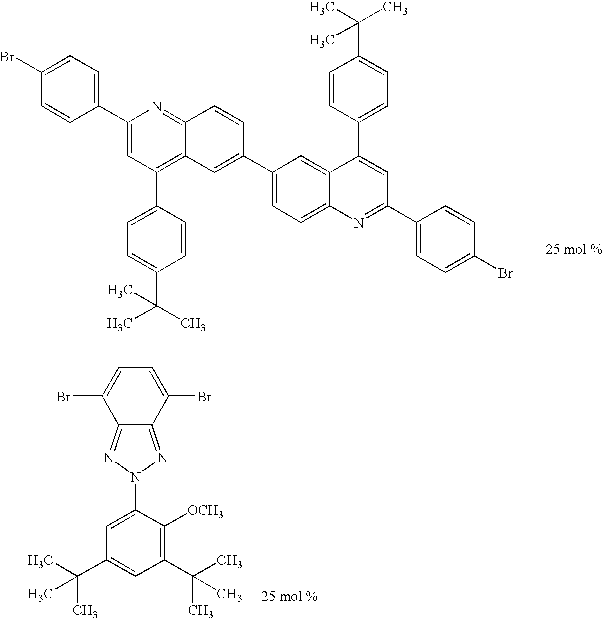 |
| (32) | 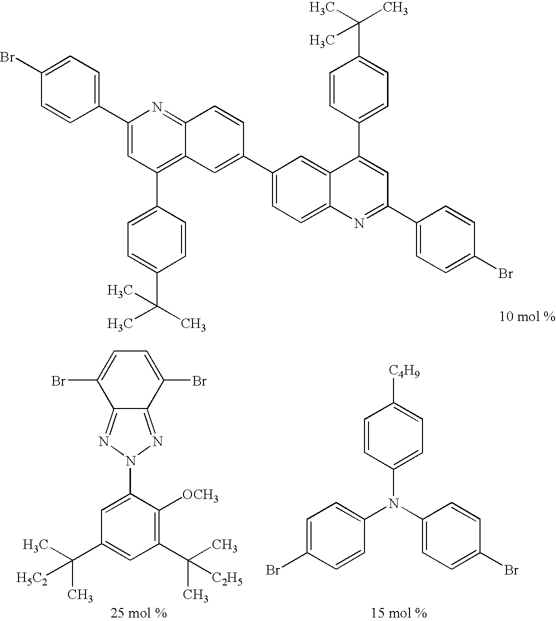 |
| (33) | 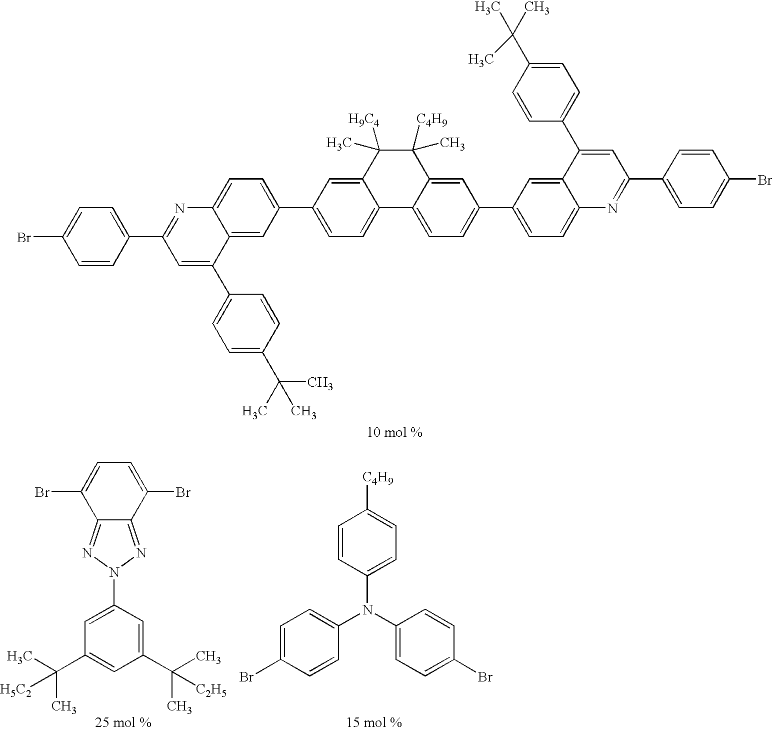 |
| (34) | 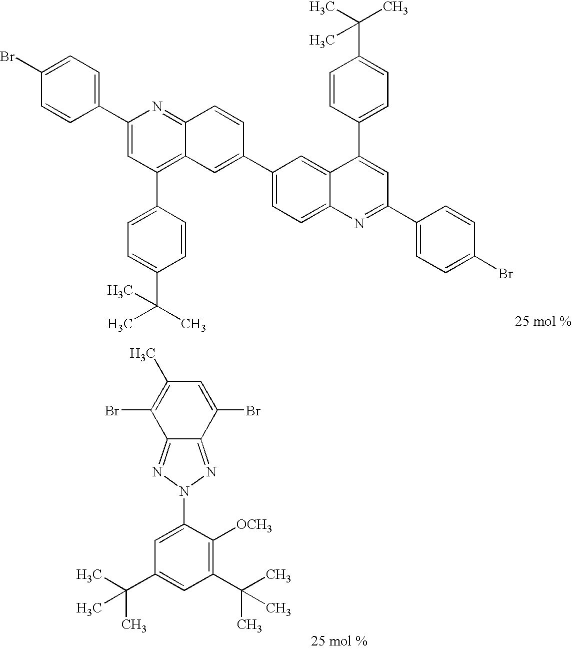 |
| (35) | 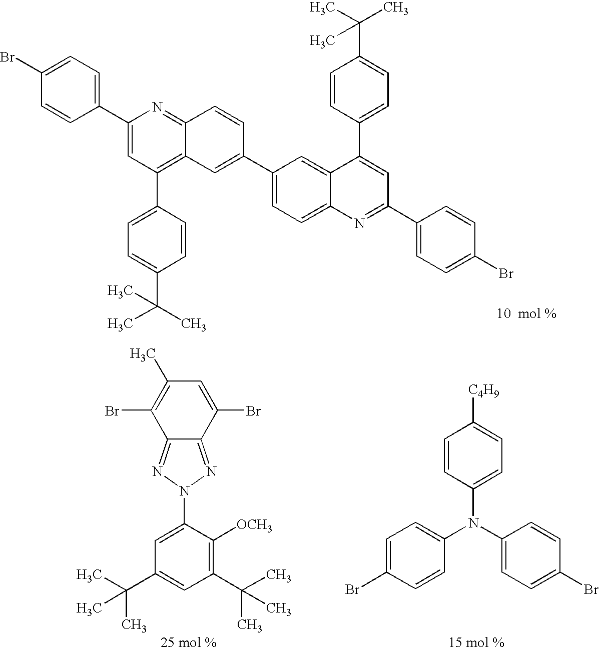 |

When the group linking each of the monomer units is —O—, that is, when D is —O— and b is 1 in Formula (II), the quinoline copolymer of the present invention can be produced by a reaction, in a polar solvent in the presence of a base, between a difluoroquinoline monomer and a dihydroxybenzotriazole derivative monomer, between a dibromobenzotriazole derivative monomer and a dihydroxyquinoline monomer, or between a dibromoquinoline monomer and a dihydroxybenzotriazole derivative monomer, as disclosed in Japanese Patent Application Laid-open No. 9-136954. This reaction is carried out by a reaction for producing the quinoline copolymer of the present invention in the presence of a base that can deprotonate a dihydroxy compound. Examples of such a base include alkali or alkaline earth metal carbonates or hydroxides such as potassium carbonate, potassium hydroxide, sodium carbonate, and sodium hydroxide. When the acidity of the dihydroxy compound is too low for it to be sufficiently deprotonated by sodium hydroxide, a stronger base such as a metal hydride, for example, sodium hydride, butyllithium, or a metal amide, for example, sodium amide, may be used. Water is generated during a reaction between this base and the dihydroxy compound. This water can be removed by azeotropic distillation. As the solvent, the above-mentioned solvents can be used.

For example, specifically, a quinoline copolymer can be produced by a reaction of a difluoroquinoline derivative represented by the formulae below 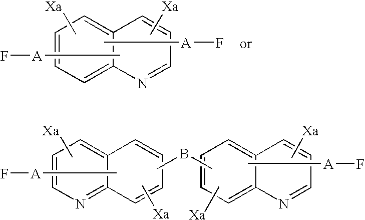
(in the formulae, X, A, B, and a are as described above) with a dihydroxybenzotriazole derivative in the presence of a base in a polar solvent.

When the quinoline copolymer of the present invention contains another copolymerizable comonomer, the above-mentioned comonomer may be copolymerized as a hydroxy monomer with the quinoline derivative and the benzotriazole derivative. Examples of this copolymerizable dihydroxy monomer in the present invention include resorcin, hydroquinone, 4,4′-dihydroxybiphenyl, 1,3-dihydroxynaphthalene, 2,6-dihydroxynaphthalene, 2,7-dihydroxynaphthalene, 3,4′-dihydroxybiphenyl, 3,3′-dihydroxybiphenyl, methyl 2,4-dihydroxybenzoate, isopropylidene diphenol (bisphenol A), phenolphthalein, phenol red, 1,2-di(4-hydroxyphenyl)ethane, di(4-hydroxyphenyl)methane, 4,4′-dihydroxybenzophenone, N,N-bis(4-hydroxyphenyl)-N-phenylamine, and N,N′-bis(4-hydroxyphenyl)-N,N′-bis(3-methylphenyl)-[1,1 ′-biphenyl]-4,4′-diamine.

The hydroxy monomer may have a substituent, and examples of the substituent include substituents represented by the above-mentioned —R¹, —OR², —SR³, —OCOR⁴, —COOR⁵, —SiR⁶R⁷R⁸, or —NR⁹R¹⁰. When there are a plurality of substituents, the plurality of substituents may be identical to or different from each other.

As specific examples of the hydroxy monomer of the present invention, example compounds are listed below, but they should not be construed as being limited thereto.

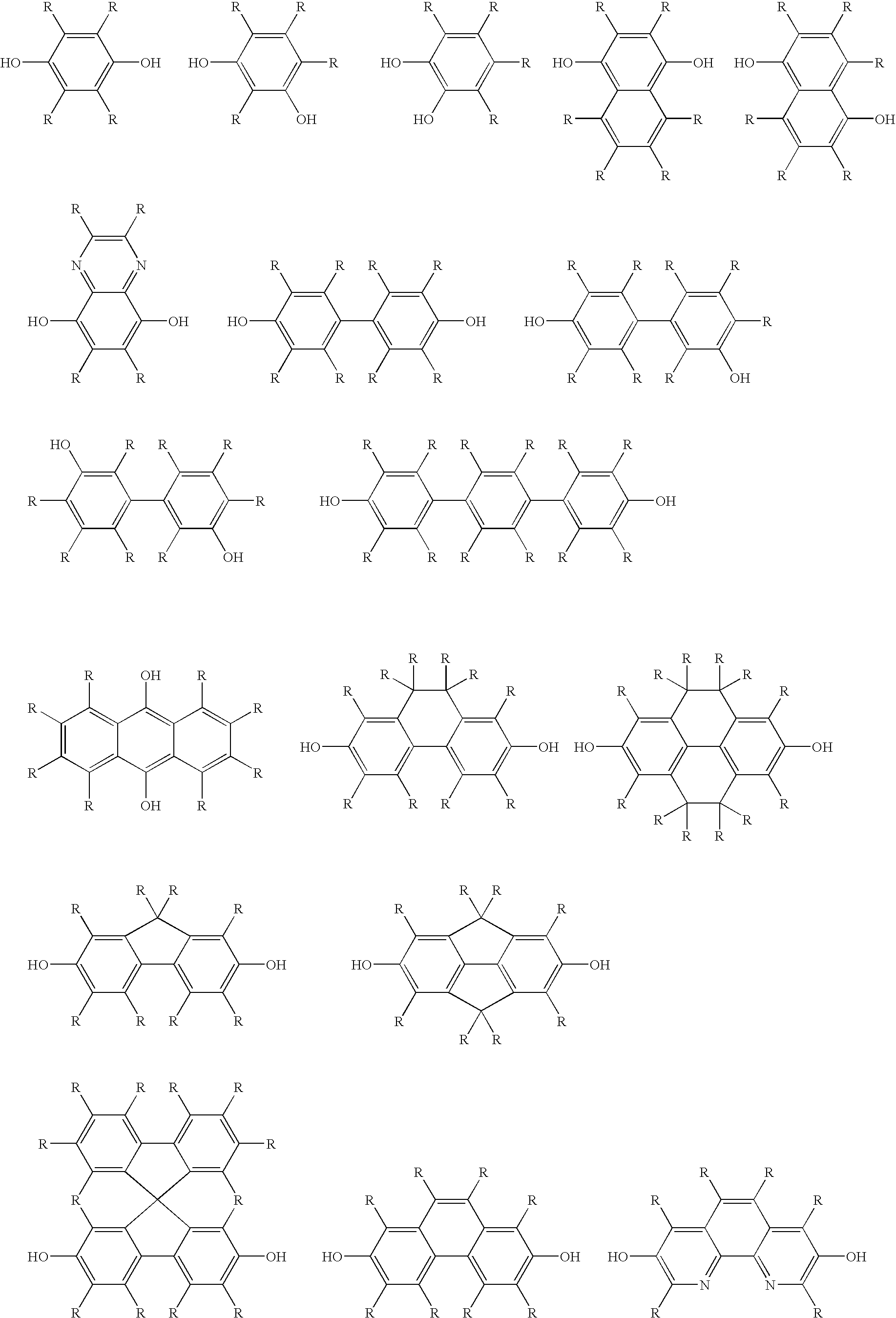

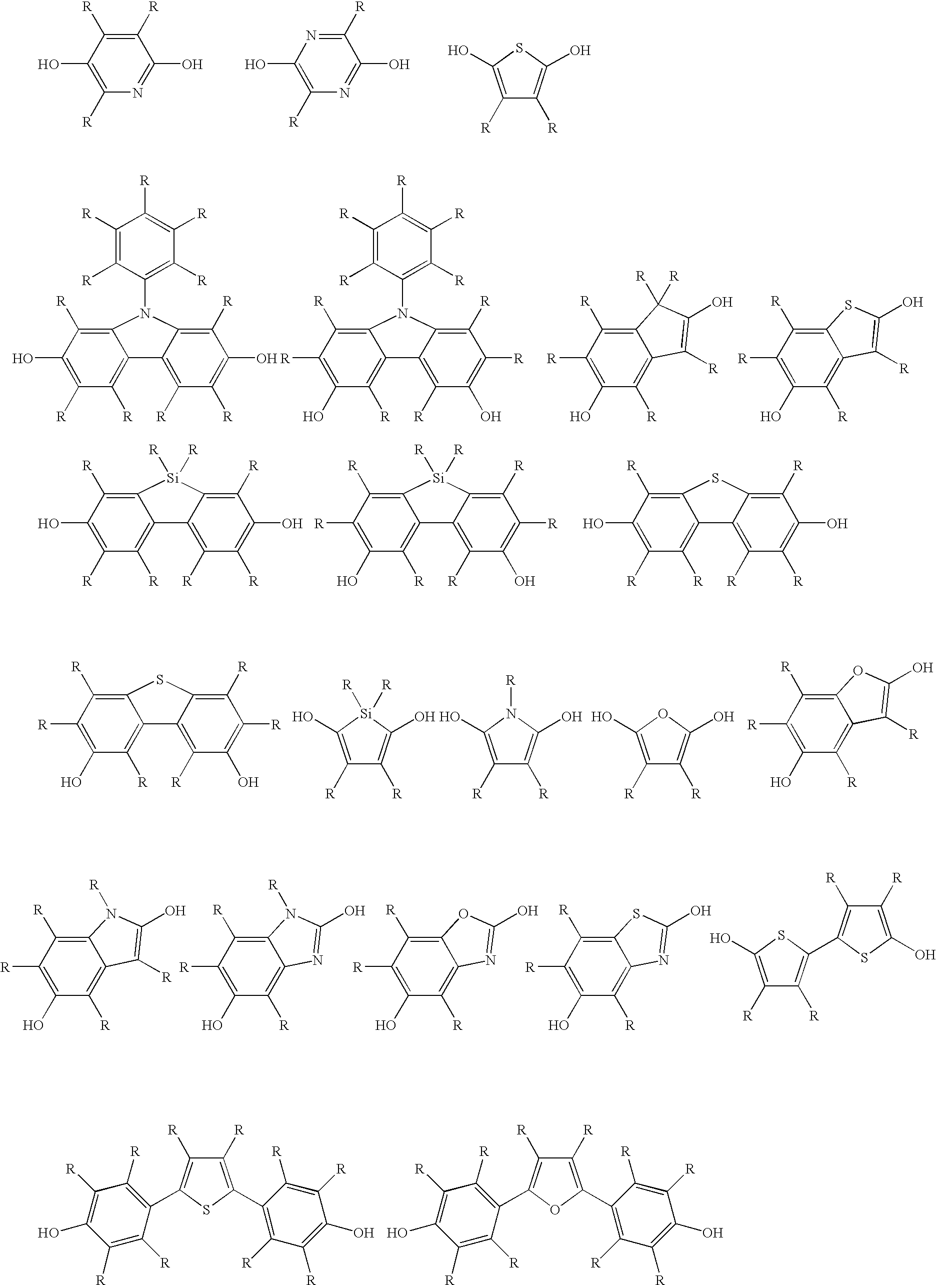

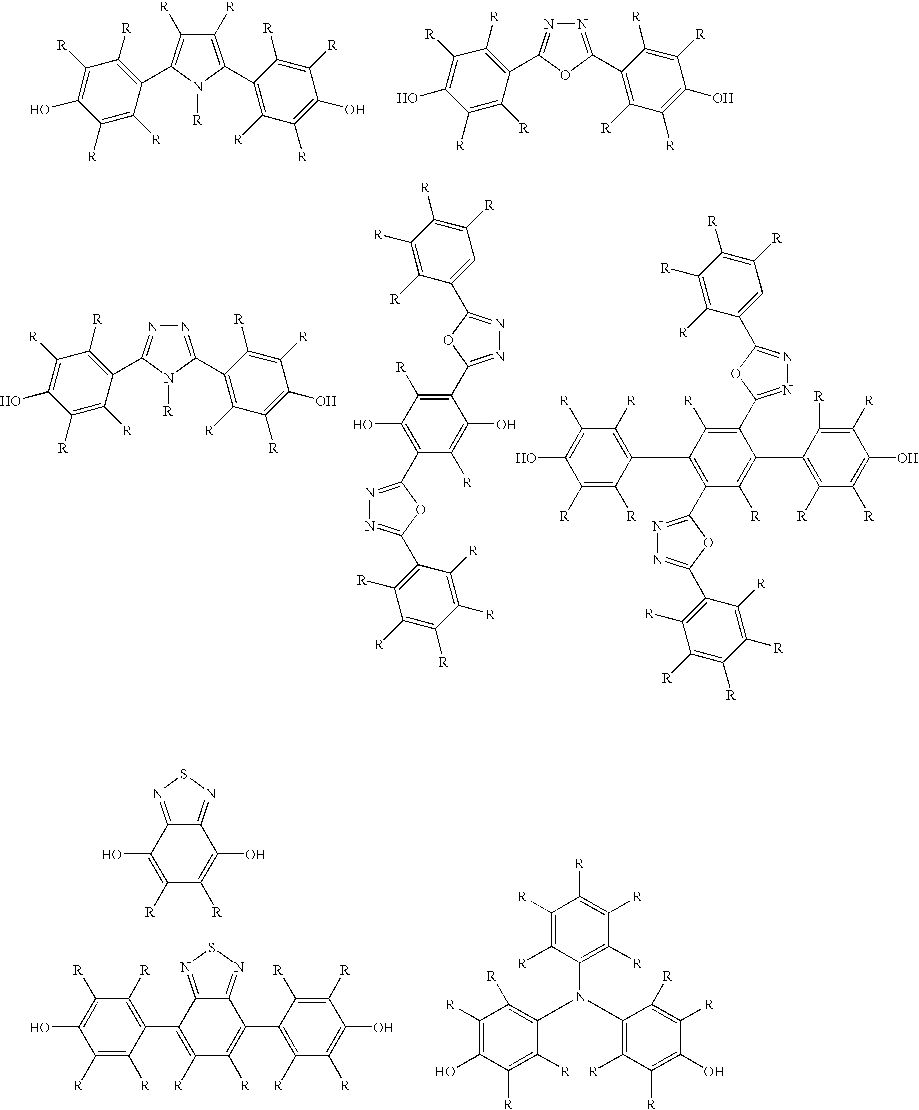

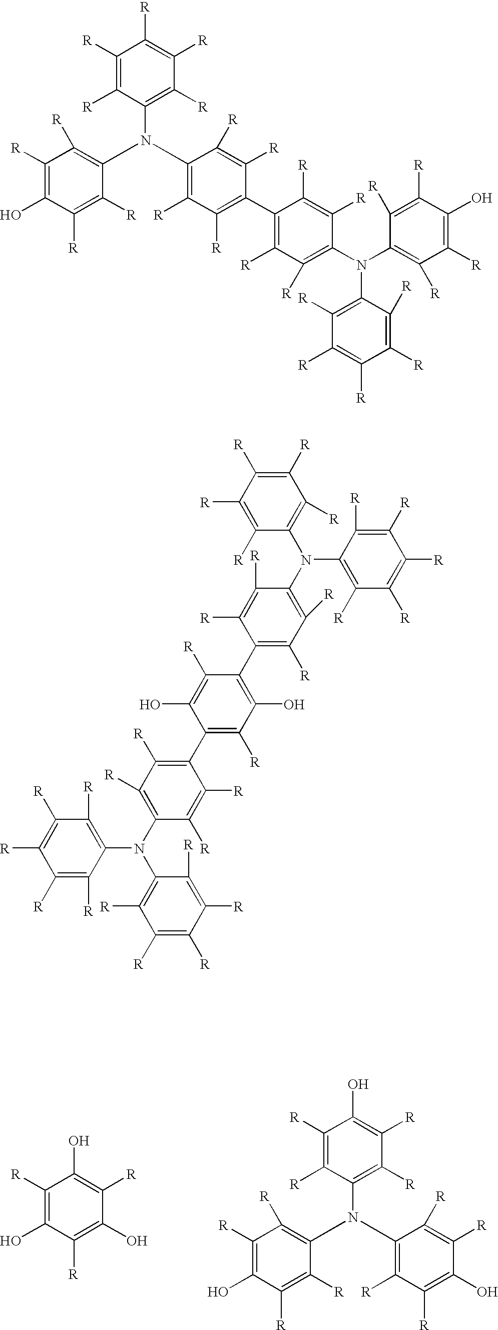

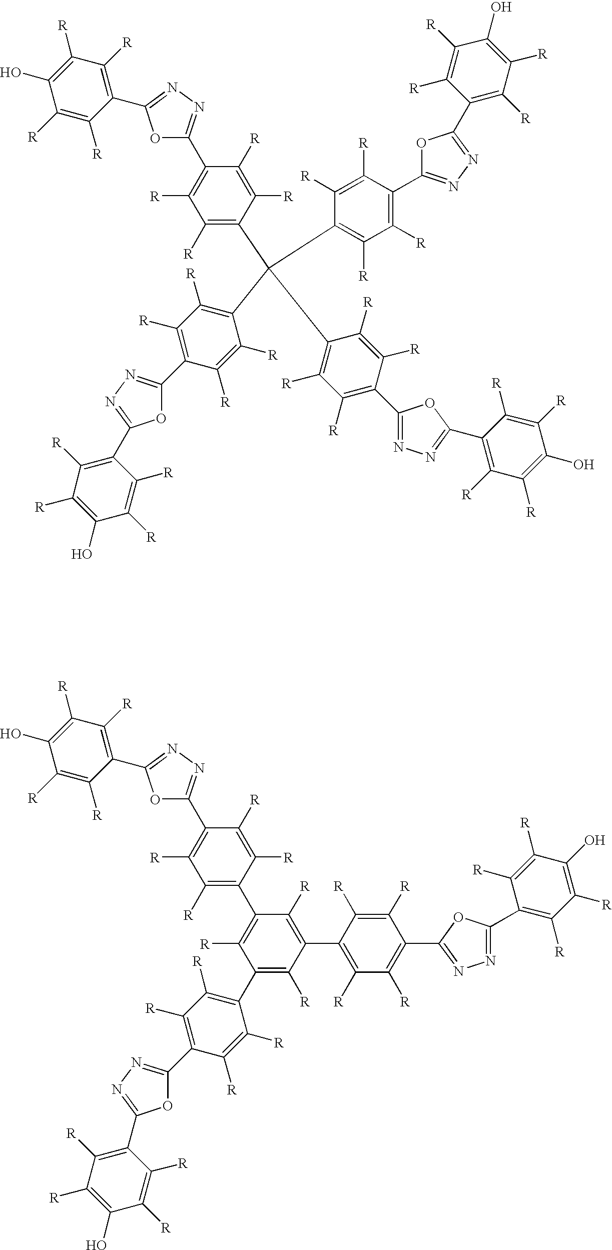

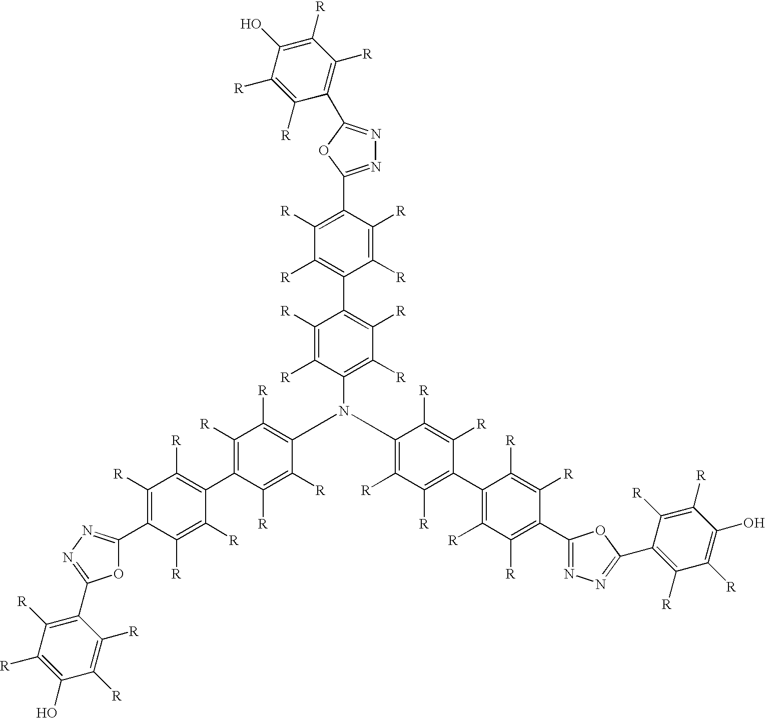

Among the above-mentioned hydroxy monomers, examples of the substituents R include substituents represented by the above-mentioned —R¹, —OR², —SR³, —OCOR⁴, —COOR⁵, —SiR⁶R⁷R⁸, or —NR⁹R¹⁰. R may be a hydrogen atom. The substituents R may be identical to or different from each other.

The molecular weight of the quinoline copolymer obtained by the above-mentioned method is preferably 10,000 to 1,000,000, and more preferably 30,000 to 800,000. When it is less than 10,000, the film-forming properties tend to deteriorate, and when it exceeds 1,000,000, the solubility tends to decrease.

The quinoline copolymer of the present invention can be used as a material of an active layer of an electroluminescent device. The active layer referred to here means a layer that is able to emit light when an electric field is applied (light-emitting layer), or a layer that improves the charge injection or the charge transporting (charge injection layer or charge transporting layer). Here, the charge means a negative or a positive charge.

The thickness of the active layer can be set as appropriate while taking into consideration the luminescence efficiency, etc., and is preferably 10 to 300 nm, and more preferably 20 to 200 nm. When it is less than 10 nm, pinholes, etc. tend to occur as thin film defects, and when it exceeds 300 nm, the properties tend to deteriorate.

Examples of an electron injection and/or electron transporting layer include layers containing materials such as an oxadiazole derivative, a benzoxazole derivative, a benzoquinone derivative, a quinoline derivative, a quinoxaline derivative, a thiadiazole derivative, a benzodiazole derivative, a triazole derivative, or a metal chelate complex compound.

Examples of a positive hole injection and/or positive hole transporting layer include layers containing materials such as copper phthalocyanine, a triphenylamine derivative, a triphenylmethane derivative, a stilbene-based compound, a hydrazone-based compound, a carbazole-based compound, a high molecular weight arylamine, a polyaniline, or a polythiophene.

In order to use the polymer of the present invention as a material of the active layer of the electroluminescent device, a substrate is coated with a solution of the polymer so as to provide the active layer on the substrate in the form of a film. This can be achieved by layering using a method known to a person skilled in the art, such as, for example, ink jet, casting, immersion, printing, or spin coating. Examples of the printing method include relief printing, intaglio printing, offset printing, lithographic printing, reverse relief offset printing, screen printing, and gravure printing. Such a layering method can be usually carried out at a temperature in the range of −20° C. to +300° C., preferably 10° C. to 100° C., and particularly preferably 15° C. to 50° C. The layered polymer solution can usually be dried at room temperature or by heating on a hot plate.

As the solvent used for the polymer solution, chloroform, methylene chloride, dichloroethane, tetrahydrofuran, toluene, xylene, mesitylene, anisole, acetone, methyl ethyl ketone, ethyl acetate, butyl acetate, ethyl cellosolve acetate, etc. can be used.

The polymer solution of the present invention may be used as a mixture with another material. Furthermore, the electroluminescent device employing the polymer of the present invention may further have a layer containing a material other than the above-mentioned polymer layered with the active layer containing the polymer of the present invention. As a material that may be used as a mixture with the polymer of the present invention, a known material such as a positive hole injection and/or positive hole transporting material, an electron injection and/or electron transporting material, a light-emitting material, or a binder polymer can be used. The material mixed may be a polymer material or a low molecular weight material.

Examples of the positive hole injection and/or positive hole transporting material that can be used include materials such as an arylamine derivative, a triphenylmethane derivative, a stilbene-based compound, a hydrazone-based compound, a carbazole-based compound, a high molecular weight arylamine, a polyaniline, and a polythiophene, and materials formed by polymerizing the above materials. Examples of the electron injection and/or electron transporting material that can be used include materials such as an oxadiazole derivative, a benzoxazole derivative, a benzoquinone derivative, a quinoline derivative, a quinoxaline derivative, a thiadiazole derivative, a benzodiazole derivative, a triazole derivative, and a metal chelate complex compound, and materials formed by polymerizing the above materials.

Examples of the light-emitting material that can be used include an arylamine derivative, an oxadiazole derivative, a perylene derivative, a quinacridone derivative, a pyrazoline derivative, an anthracene derivative, a rubrene derivative, a stilbene derivative, a coumarin derivative, a naphthalene derivative, a metal chelate complex, and a metal complex containing Ir, Pt, etc. as the central metal, materials formed by polymerizing the above materials, and polymer materials such as a polyfluorene derivative, a polyphenylenevinylene derivative, a polyphenylene derivative, and a polythiophene derivative.

As the binder polymer that can be used, one that does not greatly degrade the properties can be used. Examples of the binder polymer include polystyrene, polycarbonate, polyarylether, polyacrylate, polymethacrylate, and polysiloxane.

The quinoline copolymer is preferably contained at 0.1 to 5 wt % relative to the total weight of the polymer solution, and more preferably 0.2 to 3 wt %. When it is less than 0.1 wt %, pinholes, etc. tend to occur as thin film defects, and when it exceeds 5 wt %, unevenness in the film thickness tends to occur.

A standard structure for the electroluminescent device of the present invention comprising the polymer of the present invention is described in U.S. Pat. No. 4,539,507 and U.S. Pat. No. 5,151,629. A polymer-containing electroluminescent device is described in, for example, International Publication WO90/13148 and EP Pat. Laid-open No. 0443861.

These electroluminescent devices usually include an electroluminescent layer (light-emitting layer) between cathode and anode electrodes, at least one of which is transparent. Furthermore, at least one electron injection layer and/or electron transporting layer is inserted between the electroluminescent layer (light-emitting layer) and the cathode and, moreover, at least one positive hole injection layer and/or positive hole transporting layer is inserted between the electroluminescent layer (light-emitting layer) and the anode.

As a material for the cathode, for example, a metal or metal alloy such as Li, Ca, Mg, AL, In, Cs, Mg/Ag, or LiF is preferable. As a material for the anode, a metal (e.g. Au) or another material having metallic conductivity such as, for example, an oxide (e.g. ITO: indium oxide/tin oxide) on a transparent substrate (e.g. a glass or a transparent polymer) can be used.

The quinoline copolymer of the present invention is suitable as, for example, a material for an organic EL device. In particular, it exhibits high luminescence efficiency, good luminescence color purity, and stability and, furthermore, good film-forming properties due to ease of film formation, etc. The organic EL device of the present invention employing same therefore exhibits good luminescence color purity, and stability, and it is excellent in terms of productivity.

### EXAMPLES

The present invention is explained below with reference to examples, but is not limited thereto.

### Example 1

### Synthesis of Diboronic Acid Ester Quinoline Derivative

A Grignard reagent was prepared by gradually adding a THF solution of 6,6′-bis[2-(4-bromophenyl)-3,4-diphenylquinoline] (30 mmol) to a mixture of magnesium (1.9 g, 80 mmol) and THF under a flow of argon while stirring well. The Grignard reagent thus obtained was gradually added dropwise over 2 hours to a THF solution of trimethyl borate (300 mmol) at −78° C. while stirring well, and the mixture was then stirred at room temperature for 2 days. The reaction mixture was poured into 5% dilute sulfuric acid containing crushed ice and stirred. The aqueous solution thus obtained was extracted with toluene, and the extract was concentrated to give a colorless solid. The solid thus obtained was recrystallized from toluene/acetone (1/2) to give a diboronic acid quinoline derivative as colorless crystals (40%). The diboronic acid quinoline derivative (12 mmol) thus obtained and 1,2-ethanediol (30 mmol) were refluxed in toluene for 10 hours, and then recrystallized from toluene/acetone (1/4) to give a diboronic acid ester quinoline derivative as colorless crystals (83%).

### Example 2

### Synthesis of Copolymer (1) of Quinoline Derivative and Benzotriazole Derivative

A 2M aqueous solution of K₂CO₃ was added to a toluene solution of the dibromobenzotriazole compound represented by the structural formula below (10 mmol), the diboronic acid ester quinoline derivative synthesized in Example 1 (10 mmol), and Pd(0)(PPh₃)₄ (0.2 mmol) under a flow of argon, and the mixture was refluxed for 48 hours while stirring vigorously.

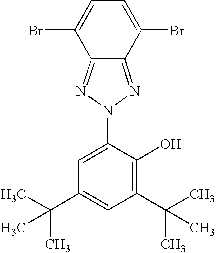

The reaction mixture was cooled to room temperature and then poured into a large amount of methanol so as to precipitate a solid. The solid thus precipitated was filtered by suction and washed with methanol to give a solid. The solid thus obtained by filtration was dissolved in toluene, and then poured into a large amount of acetone so as to precipitate a solid. The solid thus precipitated was filtered by suction, and washed with acetone to give a solid. The above-mentioned re-precipitation with acetone was repeated a further two times. Subsequently, after the solid thus obtained was dissolved in toluene, a cation/anion exchange resin (ion exchange resin manufactured by Organo Corporation) was added thereto, and the mixture was stirred for 1 hour and then filtered by suction to recover a polymer solution. The above-mentioned treatment with the ion exchange resin was repeated a further two times. The polymer solution thus recovered was poured into a large amount of methanol so as to precipitate a solid. The solid thus obtained was further extracted and washed with acetone in a Soxhlet extractor for 24 hours to give a copolymer (1) of the quinoline derivative and the benzotriazole derivative.

### Example 3

### Synthesis of Copolymer (2) of Quinoline Derivative and Benzotriazole Derivative

6,6′-Bis[2-(4-fluorophenyl)-3,4-diphenylquinoline] (10 mmol), the bisphenol benzotriazole compound represented by the structural formula below (10 mmol), potassium carbonate (15 mmol), anhydrous NMP (40 mL), and anhydrous toluene (20 mL) were heated and refluxed under a flow of nitrogen for 30 hours while stirring vigorously. After adding NMP (60 mL) to the reaction mixture, it was cooled to room temperature.

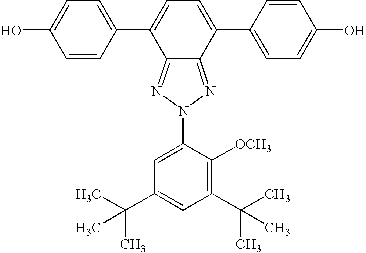

The solution thus obtained was poured into a large amount of distilled water to precipitate a solid. The solid thus precipitated was filtered by suction and washed with distilled water, methanol, and acetone to give a solid. The solid thus obtained by filtration was dissolved in toluene and then poured into a large amount of acetone to give a solid. The solid thus precipitated was filtered by suction and washed with acetone to give a solid. The above-mentioned re-precipitation with acetone was repeated a further two times. Subsequently, after the solid thus obtained was dissolved in toluene, a cation/anion exchange resin (Amberlyst EG-290-HG ion exchange resin, manufactured by Organo Corporation) was added thereto, and the mixture was stirred for 1 hour and then filtered by suction to recover a polymer solution. The above-mentioned treatment with the ion exchange resin was repeated a further two times. The polymer solution thus recovered was poured into a large amount of methanol so as to precipitate a solid. The solid thus obtained was further extracted and washed with acetone in a Soxhlet extractor for 24 hours to give a copolymer (2) of the quinoline derivative and the benzotriazole derivative.

### Example 4

### Synthesis of Copolymer (3) of Quinoline Derivative and Benzotriazole Derivative

A 2M aqueous solution of K₂CO₃ was added to a toluene solution of the dibromobenzotriazole compound represented by the structural formula below (10 mmol), the diboronic acid ester quinoline derivative synthesized in Example 1 (10 mmol), and Pd(0)(PPh₃)₄ (0.2 mmol) under a flow of argon, and the mixture was refluxed for 48 hours while stirring vigorously.

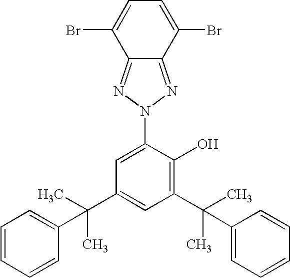

The reaction mixture was cooled to room temperature and then poured into a large amount of methanol so as to precipitate a solid. The solid thus precipitated was filtered by suction and washed with methanol to give a solid. The solid thus obtained by filtration was dissolved in toluene and then poured into a large amount of acetone so as to precipitate a solid. The solid thus precipitated was filtered by suction and washed with acetone to give a solid. The above-mentioned re-precipitation with acetone was repeated a further two times. Subsequently, after the solid thus obtained was dissolved in toluene, a cation/anion exchange resin (ion exchange resin manufactured by Organo Corporation) was added thereto, and the mixture was stirred for 1 hour and then filtered by suction so as to recover the polymer solution. The above-mentioned treatment with the ion exchange resin was repeated a further two times. The polymer solution thus recovered was poured into a large amount of methanol so as to precipitate a solid. The solid thus obtained was further extracted and washed with acetone in a Soxhlet extractor for 24 hours to give a copolymer (3) of the quinoline derivative and the benzotriazole derivative.

### Example 5

### Fabrication of Organic EL Device (1)

A toluene solution (1.0 wt %) of the copolymer (1) of the quinoline derivative and the benzotriazole derivative obtained in Example 2 was applied by spin coating to a glass substrate with a 2 mm wide ITO (indium tin oxide) patterning under an atmosphere of dry nitrogen to give a light-emitting polymer layer (film thickness 70 nm). Subsequently, it was dried by heating at 80° C./5 minutes on a hot plate under an atmosphere of dry nitrogen. The glass substrate thus obtained was transferred to vacuum vapor deposition equipment, and electrodes were formed on the above-mentioned light-emitting layer in the order LiF (film thickness 0.5 nm) and AL (film thickness 100 nm). The ITO/light-emitting polymer layer/LiF/AL device thus obtained was connected to a power supply, a voltage was applied so that the ITO was the positive electrode and the LiF/AL was the negative electrode, and at about 5 V emission of green light (λ=520 nm) was observed. No change in the color of this green light emission was observed after 500 hours at 25° C.

### Example 6

### Fabrication of Organic EL Device (2)

An ITO/light-emitting polymer layer/LiF/AL device was fabricated in the same manner as in Example 5 except that the copolymer (2) of the quinoline derivative and the benzotriazole derivative was used instead of the copolymer (1) of the quinoline derivative and the benzotriazole derivative. The ITO/light-emitting polymer layer/LiF/AL device thus obtained was connected to a power supply, a voltage was applied so that the ITO was the positive electrode and the LiF/AL was the negative electrode, and at about 9 V emission of green light (λ=522 nm) was observed. No change in the color of this green light emission was observed after 500 hours at 25° C.

### Example 7

### Fabrication of Organic EL Device (3)

An ITO/light-emitting polymer layer/LiF/AL device was fabricated in the same manner as in Example 5 except that the copolymer (3) of the quinoline derivative and the benzotriazole derivative was used instead of the copolymer (1) of the quinoline derivative and the benzotriazole derivative. The ITO/light-emitting polymer layer/LiF/AL device thus obtained was connected to a power supply, a voltage was applied so that the ITO was the positive electrode and the LiF/AL was the negative electrode, and at about 5 V emission of green light (λ=525 nm) was observed. No change in the color of this green light emission was observed after 500 hours at 25° C.

### Comparative Example 1

An ITO/light-emitting polymer layer/Ca/AL device was fabricated in the same manner as in Example 5 except that a polyquinoline represented by the structural formula below was used instead of the copolymer (1) of the quinoline derivative and the benzotriazole derivative. The ITO/light-emitting polymer layer/Ca/AL device thus obtained was connected to a power supply, a voltage was applied so that the ITO was the positive electrode and the Ca was the negative electrode, and at about 10 V emission of blue light (λ=430 nm) was observed, but the color of the light emission changed from blue to pale blue over time.

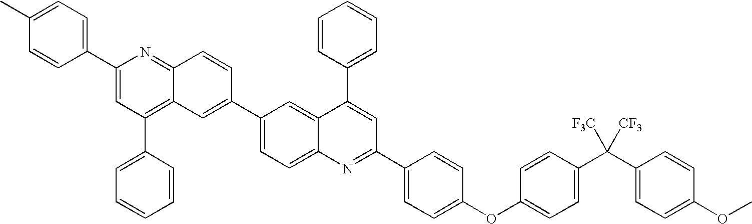

### Comparative Example 2

An ITO/light-emitting polymer layer/LiF/AL device was fabricated in the same manner as in Example 5 except that a (dioctylfluorene/benzothiazole) copolymer was used instead of the copolymer (1) of the quinoline derivative and the benzotriazole derivative. The ITO/light-emitting polymer layer/LiF/AL device thus obtained was connected to a power supply, a voltage was applied so that the ITO was the positive electrode and the LiF/AL was the negative electrode, and at about 8 V emission of yellow light (λ=548 nm) was observed, but the color of the light emission changed from yellow to whitish yellow over time.

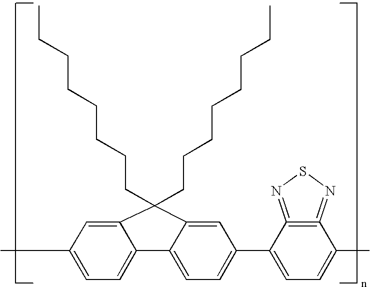

### Example 8

### Synthesis of Dibromoquinoline Derivative (3)

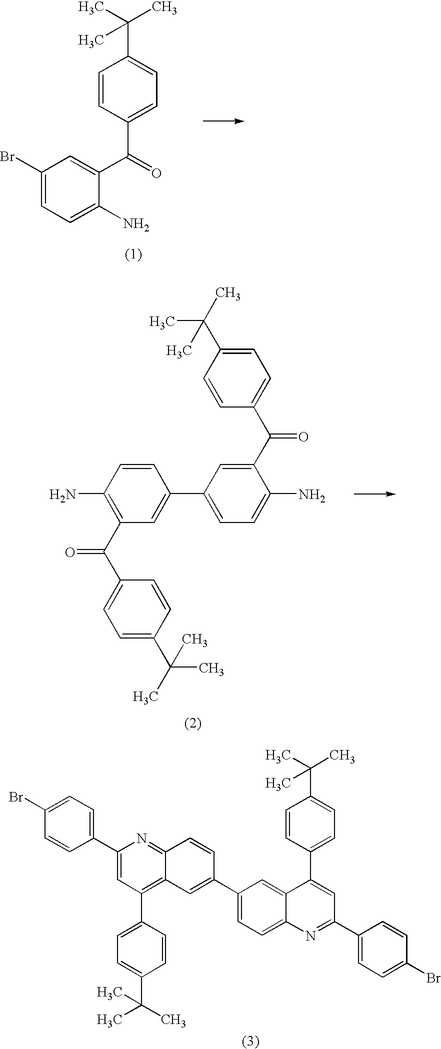

A reactor was charged with the compound (1) above (0.3 mol) and 2500 mL of dry N,N-dimethylformamide, and deaeration was carried out by blowing in argon gas (1 hour). Ni(COD)₂ (0.3 mol, 1.0 eq.) was added under an atmosphere of argon, and the mixture was stirred for 3 hours while heating at 50° C. The reaction solution was allowed to cool to room temperature and then poured into 10 L of cold water, and it was extracted with 1.5 L of ethyl acetate twice. After washing with water, it was dried with magnesium sulfate, and the solvent was removed by vacuum distillation to give compound ( as a crude product. To this crude product was added 580 mL of hexane, the mixture was heated and refluxed for 15 minutes, the solution was allowed to cool, and crystals thus precipitated were collected by filtration and dried to give compound (2) (0.11 mol). Yield 37%.

A reactor was charged with the compound (2) (0.10 mol), 4-bromoacetophenone (0.3 mol, 3.0 eq.), 400 mL of xylene, and ptoluenesulfonic acid monohydrate (3 mmol, 0.03 eq.), and the mixture was heated and refluxed for 2 days. The reaction solution was allowed to cool to room temperature, and crystals thus precipitated were then collected by filtration. 500 mL of chloroform was added to the crude crystals thus obtained, the mixture was heated and refluxed for 30 minutes, this solution was allowed to cool, and the crystals thus precipitated were collected by filtration and dried to give the target quinoline derivative (3) (0.07 mol). Yield 70%. The structure of the quinoline derivative (3) was confirmed by NMR spectroscopy, IR spectroscopy, etc.

### Example 9

### Synthesis of Quinoline Derivative (5)

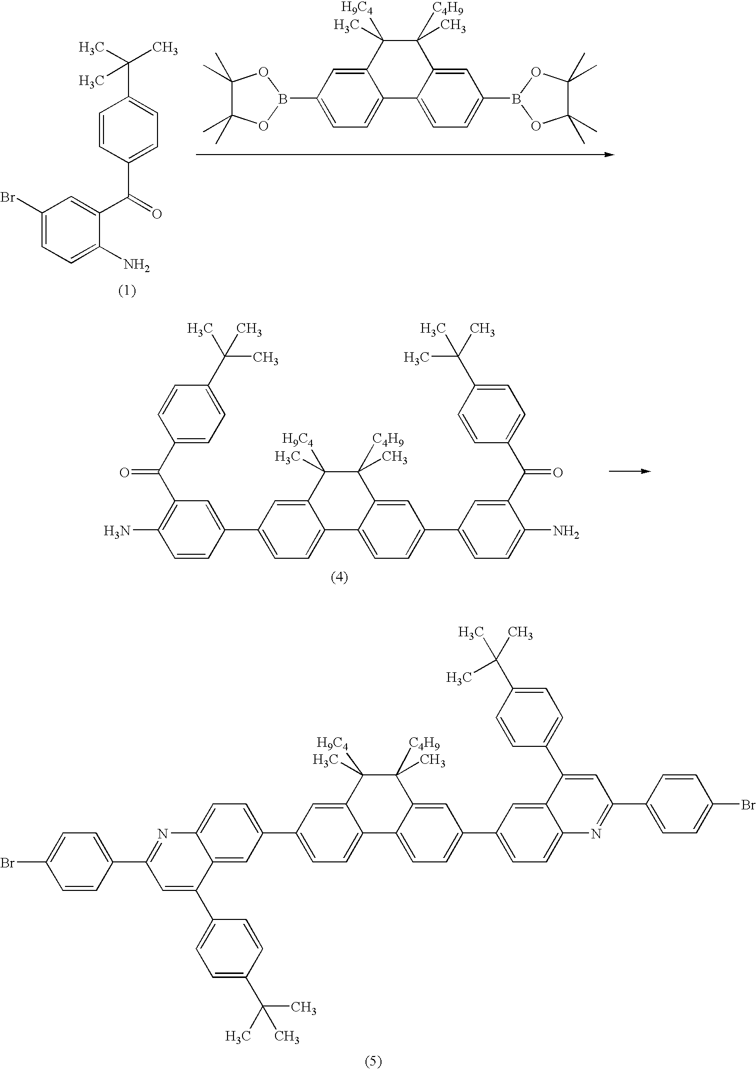

A reactor was charged with the compound (1) above (20 mmol), a dimethyldibutylphenanthrenediboronic acid ester compound (10 mmol), and Pd(O)(PPh₃)₄ (0.12 mmol), and deaeration was carried out by blowing in argon gas (1 hour). Under an atmosphere of argon, 80 mL of toluene, a 60% toluene solution of Aliquate 336 (8 mL), and 60 mL of a 2M aqueous solution of Na₂CO₃ were added, and the mixture was refluxed at 95° C. for 4 hours while stirring vigorously. After completion of the reaction, the reaction solution was poured into a large amount of cold 1/1 methanol/distilled water so as to precipitate a solid. The solid thus precipitated was filtered by suction and washed with cold methanol to give a crude product. Hexane was added to this crude product, the mixture was heated and refluxed for 15 minutes, the solution was allowed to cool, and the crystals thus precipitated were collected by filtration and dried to give compound (4) (8.3 mmol). Yield 83%.

A reactor was charged with the compound (4) (8 mmol), 4-bromoacetophenone (24 mmol, 3.0 eq.), 40 mL of xylene, and ptoluenesulfonic acid monohydrate (0.24 mmol, 0.03 eq.), and the mixture was heated and refluxed for 2 days. The reaction solution was allowed to cool to room temperature, and the crystals thus precipitated were collected by filtration. To the crude crystals thus obtained was added 50 mL of chloroform, the mixture was heated and refluxed for 30 minutes, this solution was allowed to cool, and the crystals thus precipitated were collected by filtration and dried to give the target compound (5) (5.2 mmol). Yield 65%. The structure of the quinoline derivative (5) was confirmed by NMR spectroscopy, IR spectroscopy, etc.

### Example 10

### Synthesis of Dibromobenzotriazole Compound (3): Table 1 (3)

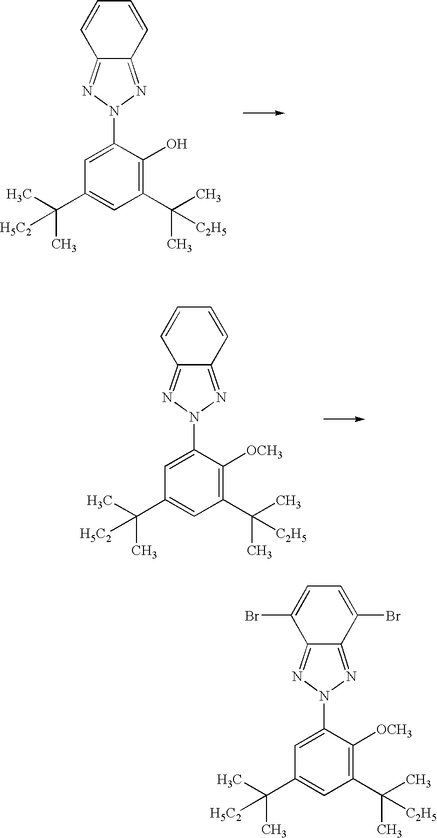

A reactor was charged with TINUVIN® 328 (0.2 mol) manufactured by Ciba Specialty Chemicals, calcium carbonate (0.3 mol), and 2000 mL of dry N,N-dimethylformamide, and deaeration was carried out by blowing in nitrogen gas (1 hour). Methyl iodide (0.4 mol) was added at 65° C. under an atmosphere of nitrogen gas, and the mixture was further heated and stirred for 3 hours. After the reaction solution was allowed to cool to room temperature, 300 mL of distilled water was added. The solution thus obtained was extracted with 300 mL of chloroform, and the extracted solution thus obtained was washed with distilled water and then concentrated to give colorless crude crystals. The crude crystals thus obtained were recrystallized from chloroform/hexane to give a methylated benzotriazole compound (0.1 mol), which was an intermediate. Yield 50%.

A reactor was charged with the methylated benzotriazole compound (0.1 mol) and a 45% acetic acid solution of hydrogen bromide (300 mL), and deaeration was carried out by blowing in nitrogen gas (1 hour). The mixture was stirred for 1 hour under an atmosphere of nitrogen gas while heating at 110° C. Subsequently, bromine (0.4 mol, 4 eq.) was added dropwise over 1 hour. After completion of the dropwise addition, the mixture was stirred for 3 hours while heating at 110° C. After the reaction solution was allowed to cool to room temperature, 300 mL of distilled water was added thereto, and the solid thus precipitated was collected by filtration. The solid thus obtained was dissolved in 500 mL of chloroform, and neutralized with a sodium hydroxide solution and a sodium hydrogen carbonate solution. The solution thus obtained was concentrated so as to give colorless crude crystals. The crude crystals thus obtained were recrystallized from acetone to give the target dibromobenzotriazole compound (3) (0.06 mol). Yield 60%. The structure of the dibromobenzotriazole compound (3) was confirmed by NMR spectroscopy, IR spectroscopy, etc.

### Example 11

### Synthesis of Copolymer (4) of Quinoline Derivative and Benzotriazole SDerivative: Synthesis of Copolymer (31) in Table 2

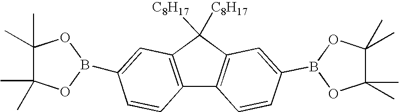

A reactor was charged with the above dioctylfluorenediboronic acid ester (5 mmol), the dibromoquinoline derivative (3) synthesized in Example 8 (2.5 mmol), the dibromobenzotriazole compound (3) synthesized in Example 10 (2.5 mmol), and Pd(0)(PPh₃)₄ (0.06 mmol), and deaeration was carried out by blowing in argon gas (1 hour). Under an atmosphere of argon, 40 mL of toluene, a 60% toluene solution of Aliquat® 336 (4 mL), and 30 mL of a 2M aqueous solution of K₂CO₃ were added, and the mixture was refluxed at 95° C. for 48 hours while stirring vigorously. After completion of the reaction, the reaction solution was poured into a large amount of 9/1 methanol/distilled water so as to precipitate a solid. The solid thus precipitated was filtered by suction and washed with methanol to give a solid. The solid thus obtained by filtration was dissolved in toluene and then poured into a large amount of 8/2 methanol/acetone so as to precipitate a solid. The solid thus precipitated was filtered by suction and washed with methanol and acetone to give a solid. The above-mentioned re-precipitation with 8/2 methanol/acetone was repeated a further two times. Subsequently, after the solid thus obtained was dissolved in toluene, a cation/anion exchange resin (ion exchange resin manufactured by Organo Corporation) was added, and the mixture was stirred for 1 hour and then filtered by suction so as to recover the polymer solution. The above-mentioned treatment with the ion exchange resin was repeated a further two times. The polymer solution thus recovered was poured into a large amount of 8/2 methanol/acetone so as to precipitate a solid. The solid thus obtained was further extracted and washed with acetone in a Soxhlet extractor for 24 hours to give a copolymer (4) of the quinoline derivative and the benzotriazole derivative.

### Example 12

### Synthesis of Copolymer (5) of Quinoline Derivative and Benzotriazole Derivative: Synthesis of Copolymer (32) in Table 2

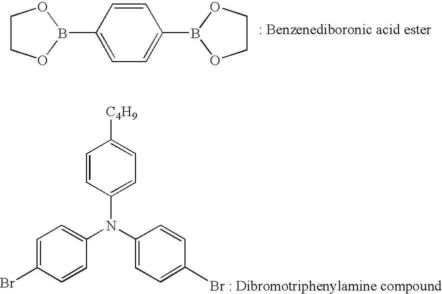

A reactor was charged with the above benzenediboronic acid ester (5 mmol), the dibromoquinoline derivative (3) synthesized in Example 8 (1 mmol), the dibromobenzotriazole compound (3) synthesized in Example 10 (2.5 mmol), the above dibrbmotriphenylamine compound (1.5 mmol), and Pd(O)(PPh₃)₄ (0.06 mmol), and deaeration was carried out by blowing in argon gas (1 hour). Under an atmosphere of argon, 40 mL of toluene, a 60% toluene solution of Aliquat® 336 (4 mL), and 30 mL of a 2M aqueous solution of K₂CO₃ were added, and the mixture was refluxed at 95° C. for 48 hours while stirring vigorously. After completion of the reaction, the reaction solution was poured into a large amount of 9/1 methanol/distilled water so as to precipitate a solid. The solid thus precipitated was filtered by suction and washed with methanol to give a solid. The solid thus obtained by filtration was dissolved in toluene and then poured into a large amount of 8/2 methanol/acetone so as to precipitate a solid. The solid thus precipitated was filtered by suction and washed with methanol and acetone to give a solid. The above-mentioned re-precipitation with the 8/2 methanol/acetone was repeated a further two times. Subsequently, after the solid thus obtained was dissolved in toluene, a cation/anion exchange resin (ion exchange resin manufactured by Organo Corporation) was added thereto, and the mixture was stirred for 1 hour and then filtered by suction so as to recover the polymer solution. The above-mentioned treatment with the ion exchange resin was repeated a further two times. The polymer solution thus recovered was poured into a large amount of 8/2 methanol/acetone so as to precipitate a solid. The solid thus obtained was further extracted and washed with acetone in a Soxhlet extractor for 24 hours to give a copolymer (5) of the quinoline derivative and the benzotriazole derivative.

### Example 13

### Synthesis of Copolymer (6) of Quinoline Derivative and Benzotriazole Derivative: Synthesis of Copolymer (33) in Table 2

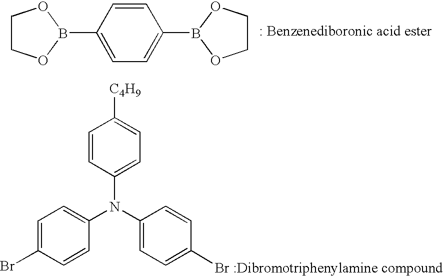

A reactor was charged with the above benzenediboronic acid ester (5 mmol), the dibromoquinoline derivative (5) synthesized in Example 9 (1 mmol), the dibromobenzotriazole compound (3) synthesized in Example 10 (2.5 mmol), the above dibromotriphenylamine compound (1.5 mmol), and Pd(0)(PPh₃)₄ (0.06 mmol), and deaeration was carried out by blowing in argon gas (1 hour). Under an atmosphere of argon, 40 mL of toluene, a 60% toluene solution of Aliquat® 336 (4 mL), and 30 mL of a 2M aqueous solution of K₂CO₃ were added, and the mixture was refluxed at 95° C. for 48 hours while stirring vigorously. After completion of the reaction, the reaction solution was poured into a large amount of 9/1 methanol/distilled water so as to precipitate a solid. The solid thus precipitated was filtered by suction and washed with methanol to give a solid. The solid thus obtained by filtration was dissolved in toluene and then poured into a large amount of 8/2 methanol/acetone so as to precipitate a solid. The solid thus precipitated was filtered by suction and washed with methanol and acetone to give a solid. The above-mentioned re-precipitation with 8/2 methanol/acetone was repeated a further two times. Subsequently, after the solid thus obtained was dissolved in toluene, a cation/anion exchange resin (ion exchange resin manufactured by Organo Corporation) was added thereto, and the mixture was stirred for 1 hour and then filtered by suction so as to recover the polymer solution. The above-mentioned treatment with the ion exchange resin was repeated a further two times. The polymer solution thus recovered was poured into a large amount of 8/2 methanol/acetone so as to precipitate a solid. The solid thus obtained was further extracted and washed with acetone in a Soxhlet extractor for 24 hours to give a copolymer (6) of the quinoline derivative and the benzotriazole derivative.

### Examples 14 to 16

### Fabrication of Organic EL Devices (4) to (6)

A glass substrate with a 2 mm wide ITO (indium tin oxide) patterning was cleaned with UV/O₃, then coated with a polythiophene/polystyrenesulfonic acid aqueous dispersion (BAYTRON P CH8000, manufactured by Bayer AG) using a spinner, and dried by heating on a hot plate at 200° C. for 15 minutes to give a hole injection layer (film thickness 40 nm). Subsequently, under an atmosphere of dry nitrogen gas, a toluene solution (1.5 wt. %) of each of the copolymers (4) to (6) of the quinoline derivative and the benzotriazole derivative obtained in Example 11 to Example 13 was applied by spin coating to give a light-emitting polymer layer (film thickness 80 nm). It was subsequently dried under an atmosphere of dry nitrogen gas by heating on a hot plate at 80° C./5 minutes. The glass substrate thus obtained was transferred to vacuum vapor deposition equipment, and electrodes were formed on the light-emitting layer in the order LiF (film thickness 0.5 nm), Ca (film thickness 20 nm), and AL (film thickness 150 nm). The ITO/light-emitting polymer layer/LiF/Ca/AL device was connected to a power supply, a voltage was applied so that the ITO was the positive electrode and the LiF/Ca/AL was the negative electrode, and the properties shown in the table below were obtained. The lifetime of the organic EL device was evaluated, and no change in the color of light emission was observed after 500 hours at 25° C.

When various monomer units in the present invention described above, other than those shown in the above-mentioned examples, are used, quinoline copolymers having excellent properties such as stability and luminescence efficiency can also be obtained.

TABLE 3

| | | Turn on | Luminance | Emission |
|---|---|---|---|---|
| Example | Polymer | voltage | efficiency | peak |
| Example 14 | Copolymer (4) | 2.5 V | 5.2 cd/A | 530 nm |
| Example 15 | Copolymer (5) | 3.0 V | 5.4 cd/A | 525 nm |
| Example 16 | Copolymer (6) | 2.5 V | 6.2 cd/A | 530 nm |

1. A quinoline copolymer comprising a quinoline monomer unit and a benzotriazole monomer unit.

2. The quinoline copolymer according to claim 1, wherein it is a copolymer comprising
a quinoline monomer unit represented by Formulae (I): 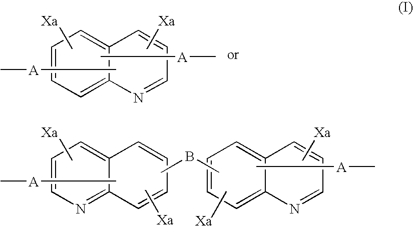
(in the formulae, each X is independently a substituent selected from the group consisting of R¹, —OR², —SR³, —OCOR⁴, —COOR⁵, and —SiR⁶R⁷R⁸ (here, R¹ to R⁸ are independently a C1 to C22 straight-chain, cyclic, or branched alkyl group, or a C2 to C20 aryl or heteroaryl group), the substituents may be identical to or different from each other and are bonded to substitutable positions of the quinoline residue, and each a is independently an integer of 0 to 3; each A is a group selected from the group consisting of a single bond and an arylene group; and B is a divalent linking group selected from the group consisting of a single bond, —O—, —S—, —C(O)—, —S(O)—, —S(O₂)—, —W—, —(—O—W—)ₘ—O—0 (m is an integer of 1 to 3), and -Q- (W is a divalent group selected from the group consisting of —Ra—, —Ar′—, —Ra—Ar′—, —Ra′—O—Ra′—, —Ra′—C(O)O—Ra′—, —Ra′—NHCO—Ra′—, —Ra—C(O)—Ra—, —Ar′—C(O)—Ar′—, -Het′-, —Ar′—S—Ar′—, —Ar′—S(O)—Ar′—, —Ar′—S(O₂)—Ar′—, and —Ar′-Q-Ar′—, Ra is an alkylene group, Ar′ is an arylene group, each Ra′ is independently a group selected from the group consisting of an alkylene group, an arylene group, and a mixed alkylene/arylene group, Het′ is a heteroarylene group, and Q is a divalent group containing a quaternary carbon)) and
an optionally substituted benzotriazole monomer unit, and
a group linking the monomer units is represented by Formula (II):
-(D) b- (II)
(in the formula, D is a divalent group selected from the group consisting of —O—, —S—, —NR—, —CR₂—, —SiR₂—, —SiR₂—O—SiR₂—, and —SiR₂—O—SiR₂—O—SiR₂— (here, each R is independently a C1 to C22 straight-chain, cyclic, or branched alkyl group, or a C2 to C20 aryl or heteroaryl group), and b is an integer of 0 to 1).

3. The quinoline copolymer according to claim 2, wherein the optionally substituted benzotriazole monomer unit is represented by Formula (III): 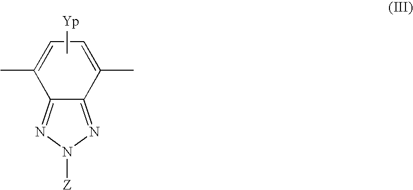
(in the formula, each Y is independently a substituent selected from the group consisting of a halogen atom, —R¹, —OR², —SR³, —OCOR⁴, —COOR⁵, and —SiR⁶R⁷R⁸ (here, R¹ to R⁸ are independently a C1 to C22 straight-chain, cyclic, or branched alkyl group, or a C2 to C20 aryl or heteroaryl group), the substituents may be identical to or different from each other and are bonded to substitutable positions of the benzene ring of the benzotriazole skeleton, and p is an integer of 0 to 2; in the formula, Z is a group selected from the group consisting of optionally substituted alkyl, aryl, and heteroaryl groups).

4. The quinoline copolymer according to claim 2, wherein X in Formulae (I) is —R¹ (here, each R¹ is independently a C1 to C22 straight-chain, cyclic, or branched alkyl group or a C2 to C20 aryl or heteroaryl group), and each a is independently an integer of 0 to 3.

5. The quinoline copolymer according to claim 2, wherein Y in Formula (III) is —R¹ (here, each R¹ is independently a C1 to C22 straight-chain, cyclic, or branched alkyl group or a C2 to C20 aryl or heteroaryl group), p is an integer of 0 to 2, and Z is an optionally substituted phenyl group.

6. An organic electroluminescent device fabricated by employing the quinoline copolymer according to claim 1.
